(19) United States
(12) Patent Application Publication
(10) Pub. No.: US 2026/0206289 A1
(43) Pub. Date: Jul. 16, 2026

(54) GATE FORMATION FOR STACKED TRANSISTORS

(71) Applicant: TAIWAN SEMICONDUCTOR MANUFACTURING COMPANY, LTD., Hsinchu (TW)

(72) Inventors: Wan Chen HSIEH, Hsinchu City (TW); Szu-Hua CHEN, Tainan City (TW); Chung-Ting KO, Kaohsiung City (TW); Pei-Ren JENG, Hsinchu County (TW)

(73) Assignee: TAIWAN SEMICONDUCTOR MANUFACTURING COMPANY, LTD., Hsinchu (TW)

(21) Appl. No.: 19/022,829

(22) Filed: Jan. 15, 2025

(51) Int. Cl. H10D 84/01; H10D 84/85

(52) U.S. Cl. CPC H10D 84/0181; H10D 84/0167; H10D 84/0188; H10D 84/851; H10D 84/856

(57) ABSTRACT

A method includes following steps. A first semiconductor nanostructure is formed, and a second semiconductor nanostructure is formed above the first semiconductor nanostructure. First and second gate dielectric layers are respectively formed on the first and second semiconductor nanostructures. A dipole dopant source layer is deposited over the first gate dielectric layer and the second gate dielectric layer. A dummy fill material is formed without performing a CMP process on the dummy fill material. The dipole dopant source layer is etched by using the dummy fill material as an etch mask. After etching the dipole dopant source layer, a dipole dopant of the dipole dopant source layer is incorporated into the first gate dielectric layer.

### BACKGROUND

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

As the semiconductor industry further progresses into sub-10 nanometer (nm) technology process nodes in pursuit of higher device density, higher performance, and lower costs, challenges from both fabrication and design issues have led to stacked device structure configurations, such as complementary field effect transistors (CFET) where an n-type multi-gate transistor and a p-type multi-gate transistor are stacked vertically, one over the other. While existing CFET structures are generally adequate, they are not satisfactory in all aspects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a complementary field-effect transistor (CFET) schematic in a three-dimensional view, in accordance with some embodiments.

FIGS. 2, 3, and 4 are three-dimensional views at various stages of CFET fabrication, in accordance with some embodiments.

FIGS. 5, 6, 7A, and 14B illustrate cross-sectional views at various stages of CFET fabrication along a similar cross-section as reference cross-section A-A′ in FIG. 1, in accordance with some embodiments.

FIGS. 7B, 8, 9A, 10-13, and 14A illustrate cross-sectional views at various stages of CFET fabrication along a similar cross-section as reference cross-section B-B′ in FIG. 1, in accordance with some embodiments.

FIG. 9B is a schematic diagram of an example deposition apparatus for performing the plasma-enhanced flowable CVD, in accordance with some embodiments of the present disclosure.

FIGS. 15-22A illustrate cross-sectional views at various stages of CFET fabrication along a similar cross-section as reference cross-section B-B′ in FIG. 1, in accordance with some embodiments.

FIG. 22B illustrates cross-sectional views at various stages of CFET fabrication along a similar cross-section as reference cross-section A-A′ in FIG. 1, in accordance with some embodiments.

FIG. 23 is a flow chat of a cyclic deposition and etching (CDE) process in accordance with some embodiments.

FIGS. 24-29A illustrate cross-sectional views at various stages of CFET fabrication along a similar cross-section as reference cross-section B-B′ in FIG. 1, in accordance with some embodiments.

FIG. 29B illustrates cross-sectional views at various stages of CFET fabrication along a similar cross-section as reference cross-section A-A′ in FIG. 1, in accordance with some embodiments.

FIG. 30 is a flow chat of a cyclic inhibition/deposition process in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 230 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced with the down-scaling of the integrated circuits.

According to various embodiments, CFETs are formed. A CFET includes a lower nanostructure-FET and an upper nanostructure-FET. Throughout the description, the terms “FET” and “transistor” are used interchangeably. In accordance with some embodiments, A CFET structure includes an NFET and a PFET, which share a common metal gate (with a common work function material). When the common metal gate has a p-type work function layer, an n-type dipole dopant is doped into the high-k dielectric layer of the NFET by diffusion from a dipole dopant source layer localized to the NFET. When the common metal gate has an n-type work function layer, a p-type dipole dopant is doped into the high-k dielectric layer of the PFET by diffusion from a dipole dopant source layer localized to the PFET.

To achieve “vertically patterning” of the dipole dopant source layer into a patterned layer localized to a lower nanostructure-FET, a dummy fill material is employed to serve as an etch stop layer during the patterning process. This dummy material includes a spin-on material that provides an etch selectivity during patterning the dipole dopant source layer. However, this approach involves one stage of chemical mechanical polish (CMP) to level the dummy material and another stage of etch-back to recess the dummy material to the desired pullback position. However, it is observed that the spin-on material exhibits a high CMP polish rate, potentially leading to excessive CMP over-polishing and hence significant loading effects across different regions on the wafer. To address these challenges, the present disclosure, in various embodiments, provides a “bottom-up” dummy material formed using a bottom-up growth approach to mitigate CMP over-polishing and loading effect issues.

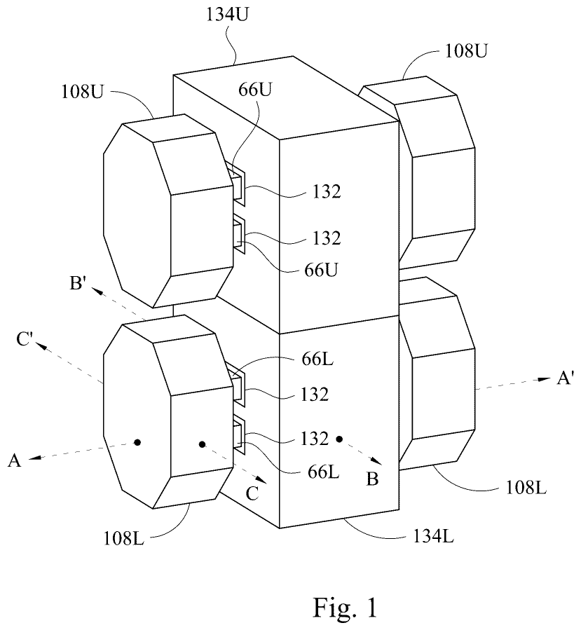

FIG. 1 illustrates an example of a CFET schematic, in accordance with some embodiments. FIG. 1 is a three-dimensional view, where some features of the CFETs are omitted for illustration clarity. While Gate-All-Around (GAA) transistors (such as nanostructure-FETs) are illustrated, the concept of the present disclosure can also be applied to the formation of other types of transistors such as planar transistors, Fin Field-Effect Transistors (FinFETs), or the like. Furthermore, in the illustrated examples, the upper FETs are PFETs, and lower FETs are NFETs, while in other embodiments, upper FETs may also be NFETs, and the lower FETs may be PFET.

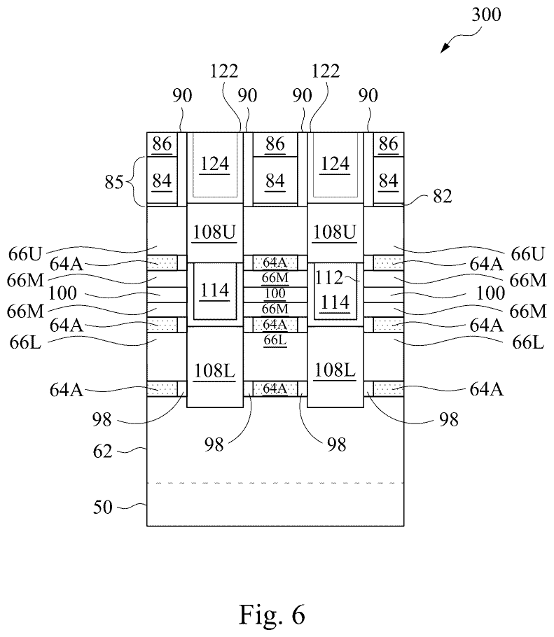

The CFETs include multiple vertically stacked nanostructure-FETs (e.g., nanowire FETs, nanosheet FETs, multi bridge channel (MBC) FETs, nanoribbon FETs, gate-all-around (GAA) FETs, or the like). For example, a CFET may include a lower nanostructure-FET of a first device type (e.g., n-type/p-type) and an upper nanostructure-FET of a second device type (e.g., p-type/n-type) that is opposite the first device type. Specifically, the CFET may include a lower PMOS transistor and an upper NMOS transistor, or the CFET may include a lower NMOS transistor and an upper PMOS transistor. Each of the nanostructure-FETs include semiconductor nanostructures 66 (including lower semiconductor nanostructures 66L and upper semiconductor nanostructures 66U), where the semiconductor nanostructures 66 act as active regions or channel regions (also referred to as channel layers, semiconductor channels regions, or semiconductor channel layers) for the nanostructure-FETs. The semiconductor nanostructures 66 may be nanosheets, nanowires, or the like. The lower semiconductor nanostructures 66L are for a lower nanostructure-FET and the upper semiconductor nanostructures 66U are for an upper nanostructure-FET. A nanostructure isolation material (not explicitly illustrated in FIG. 1, see 100 in FIG. 6) may be used to separate and electrically isolate the upper semiconductor nanostructures 66U from the lower semiconductor nanostructures 66L.

Gate dielectrics 132 are along top surfaces, sidewalls, and bottom surfaces of the semiconductor nanostructures 66. Gate electrodes 134 (including a lower gate electrode 134L and an upper gate electrode 134U) are over the gate dielectrics 132 and around the semiconductor nanostructures 66. Source/drain regions 108 (including lower epitaxial source/drain regions 108L and upper epitaxial source/drain regions 108U) are disposed at opposing sides of the gate dielectrics 132 and the gate electrodes 134. Source/drain region(s) 108 may refer to a source or a drain, individually or collectively dependent upon the context. Isolation features may be formed to separate desired ones of the source/drain regions 108 and/or desired ones of the gate electrodes 134. For example, a lower gate electrode 134L may optionally be separated from an upper gate electrode 134U by an isolation layer. Alternatively, a lower gate electrode 134L may be coupled to an upper gate electrode 134U. Further, the upper epitaxial source/drain regions 108U may be separated from lower epitaxial source/drain regions 108L by one or more dielectric layers. The isolation features between channel regions, gates, and source/drain regions allow for vertically stacked transistors, thereby improving device density. Because of the vertically stacked nature of CFETs, the schematic may also be referred to as stacking transistors or folding transistors.

FIG. 1 further illustrates reference cross-sections that are used in later figures. Cross-section A-A′ is parallel to a longitudinal axis of the semiconductor nanostructures 66 of a CFET and in a direction of, for example, a current flow between the source/drain regions 108 of the CFET. Cross-section B-B′ is perpendicular to cross-section A-A′ and along a longitudinal axis of a gate electrode 134 of a CFET. Cross-section C-C′ is parallel to cross-section B-B′ and extends through the source/drain regions 108 of the CFETs. Subsequent figures refer to these reference cross-sections for clarity.

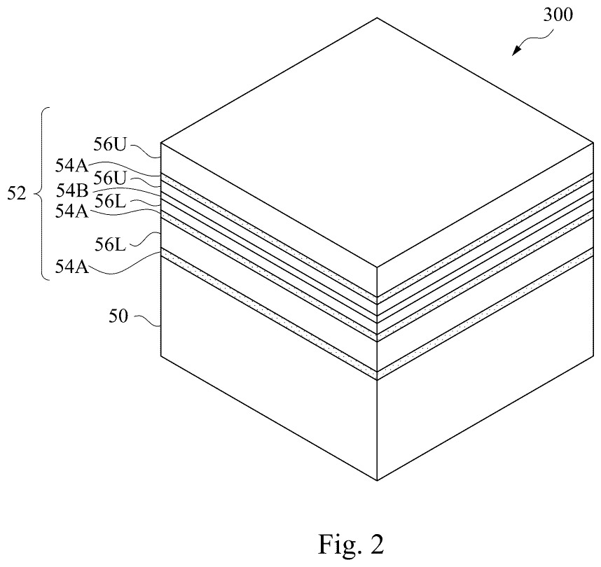

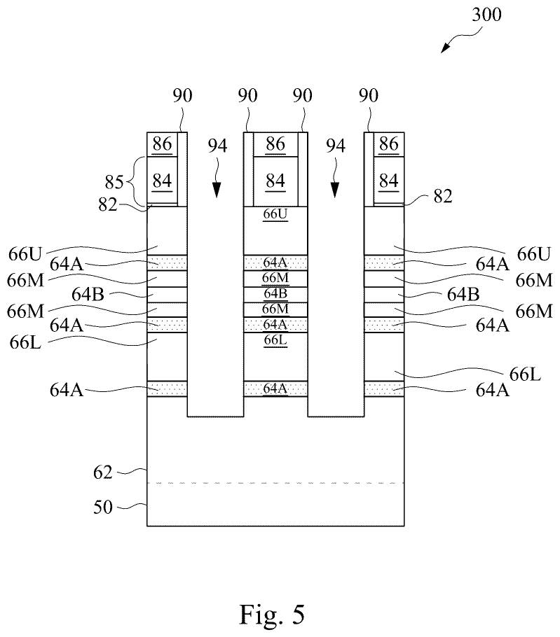

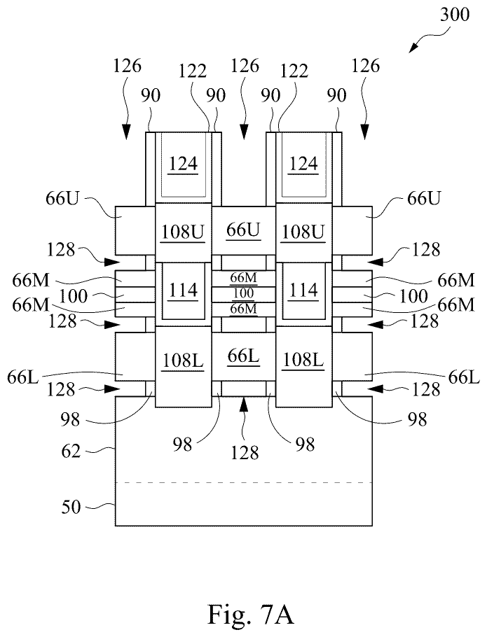

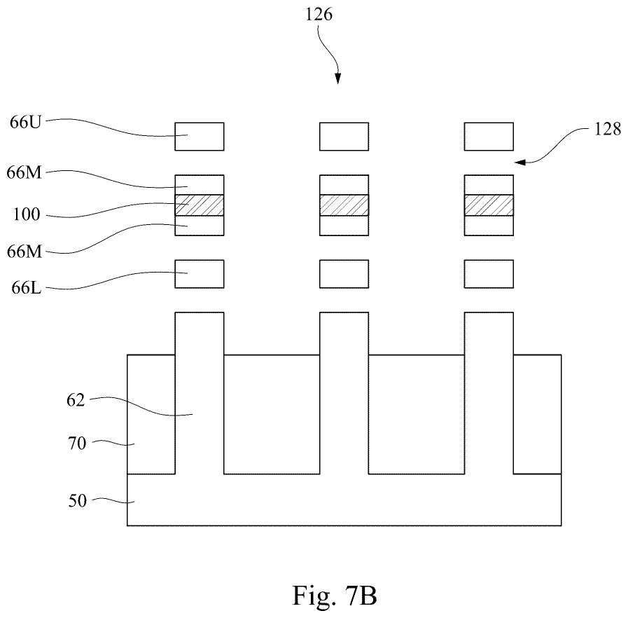

FIGS. 2-14B include three-dimensional views and cross-sectional views of a CFET device 300 at various stages of manufacturing, in accordance with some embodiments of the present disclosure. FIGS. 2, 3, and 4 are three-dimensional views showing a similar three-dimensional view as FIG. 1. FIGS. 5, 6, 7A, and 14B illustrate cross-sectional views along a similar cross-section as reference cross-section A-A′ in FIG. 1. FIGS. 7B, 8, 9A, 10-13, and 14A illustrate cross-sectional views along a similar cross-section as reference cross-section B-B′ in FIG. 1.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including carbon-doped silicon, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

A multi-layer stack 52 is formed over the substrate 50. The multi-layer stack 52 includes alternating dummy layers 54 (including first dummy layers 54A and a second dummy layer 54B) and semiconductor layers 56 (including one or more lower semiconductor layers 56L and one or more upper semiconductor layers 56U). The lower semiconductor layer 56L and a subset of the first dummy layers 54A are disposed below the second dummy layer 54B. The upper semiconductor layer 56U and another subset of the first dummy layers 54A are disposed above the second dummy layer 54B. As subsequently described in greater detail, the dummy layers 54 will be removed and the semiconductor layers 56 will be patterned to form channel regions of CFETs. Specifically, the lower semiconductor layer 56L will be patterned to form a channel region of the lower nanostructure-FET of the CFET, and the upper semiconductor layer 56U will be patterned to form a channel region of the upper nanostructure-FET of the CFET.

The multi-layer stack 52 is illustrated as including four of the dummy layers 54 and four of the semiconductor layers 56. It is appreciated that the multi-layer stack 52 may include any number of the dummy layers 54 and the semiconductor layers 56. Each layer of the multi-layer stack 52 may be grown by a process such as vapor phase epitaxy (VPE) or molecular beam epitaxy (MBE), deposited by a process such as chemical vapor deposition (CVD) or atomic layer deposition (ALD), or the like.

The first dummy layers 54A are formed of a first semiconductor material, and the second dummy layer 54B is formed of a second semiconductor material. The first and second semiconductor materials may be selected from the candidate semiconductor materials of the substrate 50. The semiconductor materials of the first dummy layers 54A and the second dummy layer 54B will be subsequently described in greater detail. The first and second semiconductor materials have a high etching selectivity to one another. As such, the material of the second dummy layer 54B may be removed at a faster rate than the material of the first dummy layers 54A in subsequent processing.

The semiconductor layers 56 (including the lower semiconductor layers 56L and upper semiconductor layers 56U) are formed of one or more semiconductor material(s). The semiconductor material(s) may be selected from the candidate semiconductor materials of the substrate 50. In some embodiments, the semiconductor layers 56 are formed of a group IV-V material or a group III-V material. The lower semiconductor layers 56L and the upper semiconductor layers 56U may be formed of the same semiconductor material, or may be formed of different semiconductor materials. In some embodiments, the lower semiconductor layers 56L and the upper semiconductor layers 56U are both be formed of a semiconductor material suitable for p-type devices and n-type devices, such as silicon. In some embodiments, the lower semiconductor layers 56L are formed of a semiconductor material suitable for p-type devices, such as germanium or silicon-germanium, and the upper semiconductor layers 56U are formed of a semiconductor material suitable for n-type devices, such as silicon or carbon-doped silicon. The semiconductor material(s) of the semiconductor layers 56 will be subsequently described in greater detail. The semiconductor material(s) of the semiconductor layers 56 have a high etching selectivity to the semiconductor materials of the dummy layers 54. As such, the materials of the dummy layers 54 may be removed at a faster rate than the material of the semiconductor layers 56 in subsequent processing.

Some layers of the multi-layer stack 52 may be thicker than other layers of the multi-layer stack 52. The thickness of the second dummy layer 54B may be different (e.g., greater or less) than the thickness of each of the first dummy layers 54A. In some embodiments, the second dummy layer 54B has a large thickness, such as a greater thickness than each of the first dummy layers 54A. Forming the second dummy layer 54B to a large thickness allows the second dummy layer 54B to be more easily removed in subsequently processing. Additionally, the thickness of each of the semiconductor layers 56 may be different (e.g., greater or less) than the thickness(es) of each of the first dummy layers 54A and/or the second dummy layer 54B. In some embodiments, each of the semiconductor layers 56 may be thicker than each of the dummy layers 54. In some embodiments, the lower semiconductor layers 56L have different thicknesses. For example, a bottommost one of the lower semiconductor layers 56L has a thickness greater than a thickness of a topmost one of the lower semiconductor layers 56L. In some embodiments, the upper semiconductor layers 56U have different thicknesses. For example, a topmost one of the upper semiconductor layers 56U has a thickness greater than a thickness of a bottommost one of the upper semiconductor layers 56U.

In some embodiments, the first dummy layers 54A are formed of silicon-germanium with a first germanium atomic percentage, the second dummy layer 54B is formed of silicon-germanium with a second germanium atomic percentage that is higher than the first germanium atomic percentage. The difference between the second germanium atomic percentage and the first germanium atomic percentage may be higher than about 30 percent, and may be in the range between about 40 percent and about 70 percent. The higher germanium atomic percentage allows the second dummy layer 54B to be etched at a faster rate than the first dummy layers 54A, and allow the second dummy layer 54B to be completed removed during a subsequent etching process, as discussed hereinafter.

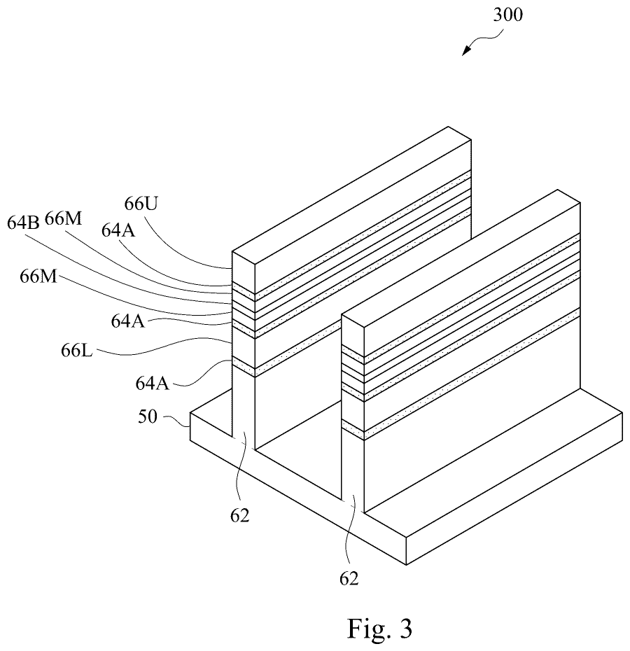

In FIG. 3, fins 62 are formed in the substrate 50 and nanostructures 64, 66 (including first dummy nanostructures 64A, second dummy nanostructures 64B, lower semiconductor nanostructures 66L, middle semiconductor nanostructures 66M, and upper semiconductor nanostructures 66U) are formed in the multi-layer stack 52. In some embodiments, the nanostructures 64, 66 and the fins 62 may be formed in the multi-layer stack 52 and the substrate 50, respectively, by etching trenches in the multi-layer stack 52 and the substrate 50. The etching may be any acceptable etch process, such as a reactive ion etch (RIE), neutral beam etch (NBE), the like, or a combination thereof. The etching may be anisotropic. Forming the nanostructures 64, 66 by etching the multi-layer stack 52 may define the first dummy nanostructures 64A from the first dummy layers 54A, the second dummy nanostructures 64B from the second dummy layer 54B, the lower semiconductor nanostructures 66L from the bottommost one of the lower semiconductor layers 56L, the upper semiconductor nanostructures 66U from the topmost one of the upper semiconductor layers 56U, and the middle semiconductor nanostructures 66M from the topmost one of the lower semiconductor layers 56L and the bottommost one of the upper semiconductor layers 56U. The first dummy nanostructures 64A and the second dummy nanostructures 64B may further be collectively referred to as the dummy nanostructures 64. The lower semiconductor nanostructures 66L and the upper semiconductor nanostructures 66U may further be collectively referred to as the semiconductor nanostructures 66.

As subsequently described in greater detail, the dummy nanostructures 64 will be removed to form vertically arranged channel regions of CFETs. Specifically, the lower semiconductor nanostructures 66L will act as channel regions for lower nanostructure-FETs of the CFETs. Additionally, the upper semiconductor nanostructures 66U will act as channel regions for upper nanostructure-FETs of the CFETs.

The middle semiconductor nanostructures 66M are the semiconductor nanostructures 66 that are directly above/below (e.g., in contact with) the second dummy nanostructures 64B. Depending on the heights of subsequently formed source/drain regions, the middle semiconductor nanostructures 66M may or may not adjoin any source/drain regions and may or may not act as functional channel regions for the CFETs. The second dummy nanostructures 64B will be subsequently replaced with isolation nanostructures. The isolation nanostructures and the middle semiconductor nanostructures 66M may define boundaries of the lower nanostructure-FETs and the upper nanostructure-FETs.

The fins 62 and the nanostructures 64, 66 may be patterned by any suitable method. For example, the fins 62 and the nanostructures 64, 66 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins 62 and the nanostructures 64, 66. In some embodiments, a mask (or other layer) may remain on the nanostructures 64, 66.

Although each of the fins 62 and the nanostructures 64, 66 are illustrated as having a constant width throughout, in other embodiments, the fins 62 and/or the nanostructures 64, 66 may have tapered sidewalls such that a width of each of the fins 62 and/or the nanostructures 64, 66 continuously increases in a direction towards the substrate 50. In such embodiments, each of the nanostructures 64, 66 may have a different width and be trapezoidal in cross-section view.

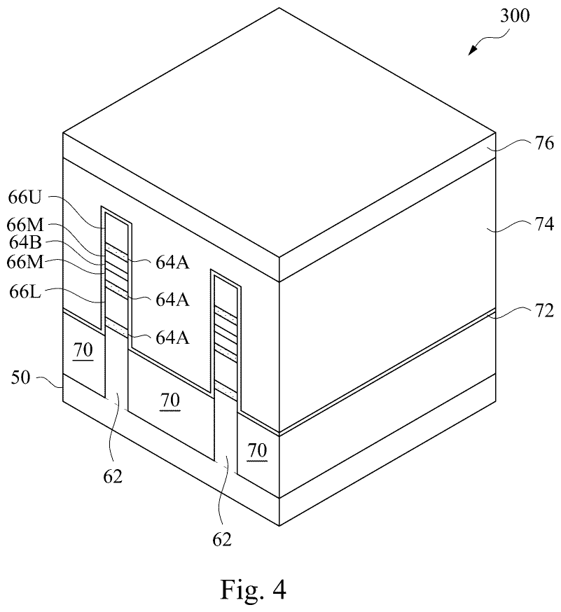

In FIG. 4, isolation regions 70 are formed adjacent to the fins 62. The isolation regions 70 may be formed by depositing an insulating material over the substrate 50, the fins 62, and nanostructures 64, 66, and between adjacent fins 62. The insulating material may be an oxide, such as silicon oxide, a nitride, the like, or a combination thereof, and may be formed by high-density plasma chemical vapor deposition (HDP-CVD), flowable chemical vapor deposition (FCVD), the like, or a combination thereof. Other insulating materials formed by any acceptable process may be used. In some embodiments, the insulating material is silicon oxide formed by an FCVD process. An anneal process may be performed once the insulating material is formed. In an embodiment, the insulating material is formed such that excess insulating material covers the nanostructures 64, 66. Although the insulating material is illustrated as a single layer, some embodiments may utilize multiple layers. For example, in some embodiments a liner (not separately illustrated) may first be formed along a surface of the substrate 50, the fins 62, and the nanostructures 64, 66. Thereafter, a fill material, such as one of the previously described insulating materials may be formed over the liner.

A removal process is then applied to the insulating material to remove excess insulating material over the nanostructures 64, 66. In some embodiments, a planarization process such as a chemical mechanical polish (CMP), an etch-back process, combinations thereof, or the like may be utilized. The planarization process exposes the nanostructures 64, 66 such that top surfaces of the nanostructures 64, 66 and the insulating material are level after the planarization process is complete.

The insulating material is then recessed to form the isolation regions 70. The insulating material is recessed such that upper portions of the fins 62 protrude from between neighboring isolation regions 70. Further, the top surfaces of the isolation regions 70 may have a flat surface as illustrated, a convex surface, a concave surface (such as dishing), or a combination thereof. The top surfaces of the isolation regions 70 may be formed flat, convex, and/or concave by an appropriate etch. The isolation regions 70 may be recessed using an etching process, such as one that is selective to the insulating material (e.g., selectively etches the insulating material at a faster rate than the materials of the fins 62 and the nanostructures 64, 66). For example, an oxide removal using, for example, dilute hydrofluoric (dHF) acid may be used.

In FIG. 4, a dummy dielectric layer 72 is formed on the fins 62 and/or the nanostructures 64, 66. The dummy dielectric layer 72 may be, for example, silicon oxide, silicon nitride, a combination thereof, or the like, and may be deposited or thermally grown according to acceptable techniques. A dummy gate layer 74 is formed over the dummy dielectric layer 72, and a mask layer 76 is formed over the dummy gate layer 74. The dummy gate layer 74 may be deposited over the dummy dielectric layer 72 and then planarized, such as by a CMP. The mask layer 76 may be deposited over the dummy gate layer 74. The dummy gate layer 74 may be a conductive or non-conductive material and may be selected from a group including amorphous silicon, polycrystalline-silicon (polysilicon), poly-crystalline silicon-germanium (poly-SiGe), or the like. The dummy gate layer 74 may be deposited by physical vapor deposition (PVD), CVD, sputter deposition, or other techniques for depositing the selected material. The dummy gate layer 74 may be formed of other materials that have a high etching selectivity to insulating materials. The mask layer 76 may include, for example, silicon nitride, silicon oxynitride, or the like. In the illustrated embodiment, the dummy dielectric layer 72 covers the isolation regions 70, such that the dummy dielectric layer 72 extends between the dummy gate layer 74 and the isolation regions 70. In another embodiment, the dummy dielectric layer 72 covers only the fins 62 and/or the nanostructures 64, 66.

Next, in FIG. 5, the mask layer 76 is patterned using acceptable photolithography and etching techniques to form masks 86. The pattern of the masks 86 is then transferred to the dummy gate layer 74 and to the dummy dielectric layer 72 to form dummy gates 84 and dummy dielectrics 82, respectively. The dummy gates 84 and the dummy dielectrics 82 are collectively referred to as dummy gate stacks 85. The dummy gates 84 cover respective channel regions of the nanostructures 64, 66. The pattern of the masks 86 may be used to physically separate each of the dummy gates 84 from adjacent dummy gates 84. The dummy gates 84 may also have a lengthwise direction (i.e., longitudinal direction) substantially perpendicular to the lengthwise direction of respective fins 62. The masks 86 can optionally be removed after patterning, such as by any acceptable etching technique.

In FIG. 5, gate spacers 90 are formed over the nanostructures 64, 66 and on exposed sidewalls of the masks 86 (if present), the dummy gates 84, and the dummy dielectrics 82. The gate spacers 90 may be formed by conformally forming one or more dielectric material(s) and subsequently etching the dielectric material(s). Acceptable dielectric materials may include silicon oxide, silicon nitride, silicon oxynitride, silicon oxycarbonitride, or the like, which may be formed by a deposition process such as chemical vapor deposition (CVD), atomic layer deposition (ALD), or the like. Other dielectric materials formed by any acceptable process may be used. Any acceptable etch process, such as a dry etch, may be performed to pattern the dielectric material(s). The etching may be anisotropic. The dielectric material(s), when etched, have portions left on the sidewalls of the dummy gates 84 (thus forming the gate spacers 90). Fin spacers may also be formed as part of forming the gate spacers 90.

Source/drain recesses 94 are formed in the nanostructures 64, 66, and the fins 62. Epitaxial source/drain regions will be subsequently formed in the source/drain recesses 94. The source/drain recesses 94 may extend through the nanostructures 64, 66 and into the fins 62. The fins 62 may be etched such that bottom surfaces of the source/drain recesses 94 are disposed above, below, or level with the top surfaces of the isolation regions 70. The source/drain recesses 94 may be formed by etching the nanostructures 64, 66, and the substrate 50 using anisotropic etching processes, such as RIE, NBE, or the like. The gate spacers 90 and the dummy gates 84 mask portions of the nanostructures 64, 66, and the fins 62 during the etching processes used to form the source/drain recesses 94. A single etch process or multiple etch processes may be used to etch each layer of the nanostructures 64, 66, and the fins 62. Timed etch processes may be used to stop the etching of the source/drain recesses 94 after the source/drain recesses 94 reach a desired depth.

Next, in FIG. 6, inner spacers 98 and dielectric isolation layers 100 are formed. Forming inner spacers 98 and dielectric isolation layers 100 (also referred to as isolation nanostructures 100) may include an etching process that laterally etches the dummy nanostructures 64A and removes the dummy nanostructure 64B. The etching process may be isotropic and may be selective to the material of the dummy nanostructures 64, so that the dummy nanostructures 64 are etched at a faster rate than the semiconductor nanostructures 66. The etching process may also be selective to the material of the dummy nanostructures 64B, so that the dummy nanostructures 64B are etched at a faster rate than the dummy nanostructures 64A. In this manner, the dummy nanostructures 64B may be completely removed from between the middle semiconductor nanostructures 66M without completely removing the dummy nanostructures 64A. In some embodiments where the dummy nanostructures 64B are formed of germanium or silicon germanium with a higher germanium atomic percentage than the dummy nanostructures 64A, the dummy nanostructures 64A are formed of silicon germanium with a lower germanium atomic percentage than the dummy structures 64B, and the semiconductor nanostructures 66 are formed of silicon free from germanium, the etch process may comprise a dry etch process using chlorine-containing gas, with or without a plasma. Because the dummy gate stacks 85 wrap around sidewalls of the semiconductor nanostructures 66 (see FIG. 4), the dummy gate stacks 85 may support the upper semiconductor nanostructures 66U so that the upper semiconductor nanostructures 66U do not collapse upon removal of the dummy nanostructures 64B. Further, although sidewalls of the dummy nanostructures 64A are illustrated as being straight after the etching, the sidewalls may be concave or convex.

Inner spacers 98 are formed on sidewalls of the recessed dummy nanostructures 64A, and dielectric isolation layers 100 are formed between the middle semiconductor nanostructures 66M. As subsequently described in greater detail, source/drain regions will be subsequently formed in the source/drain recesses 94, and the dummy nanostructures 64A will be replaced with corresponding gate structures. The inner spacers 98 act as isolation features between the subsequently formed source/drain regions and the subsequently formed gate structures. Further, the inner spacers 98 may be used to prevent damage to the subsequently formed source/drain regions by subsequent etch processes, such as the etch processes used to form gate structures. Dielectric isolation layers 100, on the other hand, are used to isolate the upper semiconductor nanostructures 66U (collectively) from the lower semiconductor nanostructures 66L (collectively). Further, the middle semiconductor nanostructures 66M and the dielectric isolation layers 100 may define the boundaries of the lower nanostructure-FETs and the upper nanostructure-FETs.

The inner spacers 98 and the dielectric isolation layers 100 may be formed by conformally depositing an insulating material in the source/drain recesses 94, on sidewalls of the dummy nanostructures 64A, and between the middle semiconductor nanostructures 66M, and then etching the insulating material. The insulating material may be a non-low-k dielectric material, which may be a carbon-containing dielectric material such as silicon oxycarbonitride, silicon oxycarbide, or the like. The insulating material may be formed by a deposition process, such as ALD, CVD, or the like. The etching of the insulating material may be anisotropic or isotropic. The insulating material, when etched, has portions remaining in the sidewalls of the dummy nanostructures 64A (thus forming the inner spacers 98) and has portions remaining in between the middle semiconductor nanostructures 66M (thus forming the dielectric isolation layers 100).

As also illustrated by FIG. 6, lower epitaxial source/drain regions 108L and upper epitaxial source/drain regions 108U are formed. The lower epitaxial source/drain regions 108L are formed in the lower portions of the source/drain recesses 94. The lower epitaxial source/drain regions 108L are in contact with the lower semiconductor nanostructures 66L and are not in contact with the upper semiconductor nanostructures 66U. Inner spacers 98 electrically insulate the lower epitaxial source/drain regions 108L from the dummy nanostructures 64A, which will be replaced with replacement gates in subsequent processes.

The lower epitaxial source/drain regions 108L are epitaxially grown, and have a conductivity type that is suitable for the device type (p-type or n-type) of the lower nanostructure-FETs. When lower epitaxial source/drain regions 108L are n-type source/drain regions, the respective material may include silicon or carbon-doped silicon, which is doped with an n-type dopant such as phosphorous, arsenic, or the like. When lower epitaxial source/drain regions 108L are p-type source/drain regions, the respective material may include silicon or silicon germanium, which is doped with a p-type dopant such as boron, indium, or the like. The lower epitaxial source/drain regions 108L may be in-situ doped, and may be, or may not be, implanted with the corresponding p-type or n-type dopants. During the epitaxy of the lower epitaxial source/drain regions 108L, the upper semiconductor nanostructures 66U may be masked to prevent undesired epitaxial growth on the upper semiconductor nanostructures 66U. After the lower epitaxial source/drain regions 108L are grown, the masks on the upper semiconductor nanostructures 66U may then be removed.

As a result of the epitaxy processes used for forming the lower epitaxial source/drain regions 108L, upper surfaces of the lower epitaxial source/drain regions 108L have facets which expand laterally outward beyond sidewalls of the nanostructures 64 and 66. In some embodiments, adjacent lower epitaxial source/drain regions 108L remain separated after the epitaxy process is completed. In other embodiments, these facets cause neighboring lower epitaxial source/drain regions 108L of a same FET to merge.

A first contact etch stop layer (CESL) 112 and a first interlayer dielectric (ILD) 114 are formed over the lower epitaxial source/drain regions 108L. The first CESL 112 may be formed of a dielectric material having a high etching selectivity from the etching of the first ILD 114, such as silicon nitride, silicon oxide, silicon oxynitride, or the like, which may be formed by any suitable deposition process, such as CVD, ALD, or the like. The first ILD 114 may be formed of a dielectric material, which may be deposited by any suitable method, such as CVD, plasma-enhanced CVD (PECVD), or FCVD. The applicable dielectric material of the first ILD 114 may include phospho-silicate glass (PSG), boro-silicate glass (BSG), boron-doped phospho-silicate glass (BPSG), undoped silicate glass (USG), silicon oxide, or the like.

The formation processes may include depositing a conformal CESL layer, depositing a material for the first ILD 114, followed by a planarization process and then an etch-back process. In some embodiments, the first ILD 114 is etched first, leaving the first CESL 112 unetched. An anisotropic etching process is then performed to remove the portions of the first CESL 112 higher than the recessed first ILD 114. After the recessing, the sidewalls of the upper semiconductor nanostructures 66U are exposed.

Upper epitaxial source/drain regions 108U are then formed in the upper portions of the source/drain recesses 94. The upper epitaxial source/drain regions 108U may be epitaxially grown from exposed surfaces of the upper semiconductor nanostructures 66U. The materials of upper epitaxial source/drain regions 108U may be selected from the same candidate group of materials for forming lower source/drain regions 108L, depending on the desired conductivity type of upper epitaxial source/drain regions 108U. The conductivity type of the upper epitaxial source/drain regions 108U may be opposite the conductivity type of the lower epitaxial source/drain regions 108L. For example, the upper epitaxial source/drain regions 108U may be oppositely doped from the lower epitaxial source/drain regions 108L. The upper epitaxial source/drain regions 108U may be in-situ doped, and/or may be implanted, with an n-type or p-type dopant. Adjacent upper source/drain regions 108U may remain separated after the epitaxy process or may be merged.

After the epitaxial source/drain regions 108U are formed, a second CESL 122 and a second ILD 124 are formed. The materials and the formation methods may be similar to the materials and the formation methods of first CESL 112 and first ILD 114, respectively, and are not discussed in detail herein. The formation process may include depositing the layers for the second CESL 122 and the second ILD 124, and performing a planarization process to remove the excess portion of the corresponding layers. After the planarization process, top surfaces of the second ILD 124, the second CESL 122, the gate spacers 90, and the masks 86 are coplanar (within process variations). The planarization process may leave masks 86 unremoved (as shown), or may remove the masks 86, in which case the top surface of the second ILD 124 is level with the top surface of the dummy gate stacks 85.

Next, in FIGS. 7A and 7B, the mask 86 (if not removed already) is removed, e.g., by a CMP process. Next, the dummy gate stacks 85 are removed in one or more etching steps, so that gate trenches 126 are formed between the gate spacers 90. In some embodiments, the dummy gates 84 and the dummy dielectrics 82 are removed by an anisotropic dry etch process. For example, the etching process may include a dry etch process using reaction gas(es) that selectively etch the material of the dummy gates 84. Each of the gate trenches 126 exposes and/or overlies portions of nanostructures 64, 66 which act as the channel regions in the resulting devices. The portions of the nanostructures 66 which act as the channel regions are disposed between neighboring pairs of the lower epitaxial source/drain regions 108L or between neighboring pairs of the upper epitaxial source/drain regions 108U. During the removal, the dummy dielectrics 82 may be used as etch stop layers when the dummy gates 84 are etched. The dummy dielectrics 82 may then be removed after the removal of the dummy gates 84.

The remaining portions of the first dummy nanostructures 64A are then removed to form openings 128 in regions between the semiconductor nanostructures 66. In some embodiments where the semiconductor nanostructures 66 are nanosheets, the openings 128 can be referred to as sheet-to-sheet spaces. The remaining portions of the first dummy nanostructures 64A can be removed by any acceptable etch process that selectively etches the material of the first dummy nanostructures 64A at a faster rate than the materials of the semiconductor nanostructures 66, the inner spacers 98, and the isolation nanostructures 100. The etching may be isotropic. For example, when the first dummy nanostructures 64A are formed of silicon-germanium, the semiconductor nanostructures 66 are formed of silicon, the inner spacers 98 are formed of silicon oxycarbonitride, and the isolation nanostructures 100 are formed of silicon oxycarbonitride, the etch process may be a wet etch using tetramethylammonium hydroxide (TMAH), ammonium hydroxide (NH₄OH), or the like. In some embodiments, a trim process (not separately illustrated) is performed to decrease the thicknesses of the exposed portions of the semiconductor nanostructures 66 and expand the openings 128.

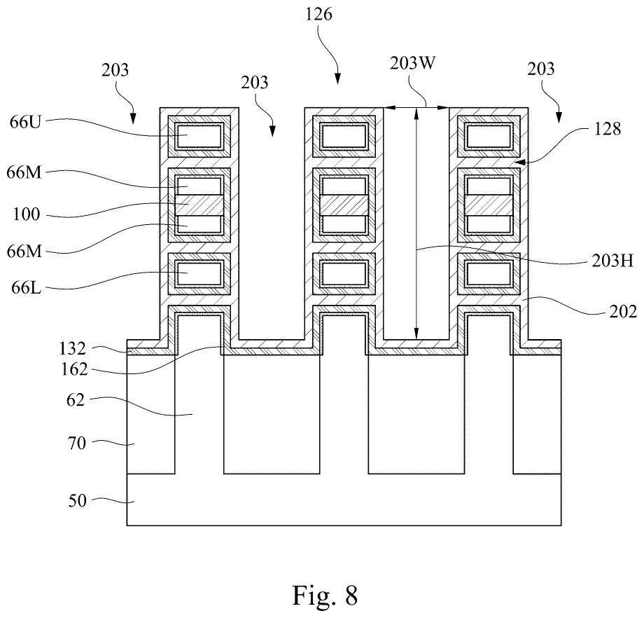

In FIG. 8, gate dielectrics 132 are formed (e.g., conformally) over the nanostructures 66. In some embodiments, interfacial layers 162 are formed at exposed surfaces of the nanostructures 66 and the fins 62. In some embodiments, the interfacial layer 162 is formed of an oxide of a group II-VI material or an oxide of a group IV material. In the illustrated embodiment, the interfacial layer 162 is an oxide of the material of the nanostructures 66, and is formed by an oxidization process (e.g., a thermal oxidization process). In other words, the interfacial layer 162 is formed by converting (e.g., oxidizing) exterior portions of the nanostructures 66 into an oxide of the material of the nanostructures 66. As a result, the interfacial layer 162 is not formed on, e.g., the isolation nanostructures 100 and the isolation regions 70, in the illustrated embodiment. In other embodiments, the interfacial layer 162 is formed by a deposition process (e.g., CVD), in which case the interfacial layer 162 is also formed on, e.g., the isolation nanostructures 100 and the isolation regions 70. In some embodiments, the interfacial layer 162 is omitted. These and other variations are fully intended to be included within the scope of the present disclosure.

Next, gate dielectric layers 132 are formed (e.g., conformally) over the interfacial layer 162 and along sidewalls of the isolation nanostructures 100, such that the gate dielectric layer 132 conformally lines the gate trenches 126 and the openings 128. Specifically, the gate dielectric layers 132 are formed on the top surfaces of the fins 62; on the top surfaces, the sidewalls, and the bottom surfaces of the semiconductor nanostructures 66; along sidewalls of the isolation nanostructures 100; and along the sidewalls of the gate spacers 90. A gate dielectric layer 132 wraps around all (e.g., four) sides of a corresponding semiconductor nanostructure 66. The gate dielectric layers 132 may also be formed on the sidewalls of the fins 62 (e.g., in embodiments where the top surfaces of the isolation regions 70 are below the top surfaces of the fins 62).

The gate dielectric layers 132 may include an oxide such as silicon oxide or a metal oxide, a silicate such as a metal silicate, combinations thereof, multi-layers thereof, or the like. The gate dielectric layers 132 may be high-k dielectric layers including a high-dielectric constant (high-k) material having a k-value greater than about 7.0, such as a metal oxide or a silicate of hafnium, aluminum, zirconium, lanthanum, manganese, barium, titanium, lead, and combinations thereof. The formation methods of the gate dielectric layers 132 may include molecular-beam deposition (MBD), ALD, PECVD, and the like.

After forming the gate dielectric layers 132, a dipole dopant source layer 202 is deposited on the gate dielectric layers 132. The deposition process may include a conformal deposition process such as ALD, CVD, or the like. In some embodiments, the dipole dopant source layer 202 comprises a p-type dipole dopant. When the p-type dopant is incorporated into the gate dielectric layers 132 of p-type FETs, it can adjust the effective work function towards a p-type characteristic, thereby lowering the threshold voltages of the associated p-type FETs. In some embodiments where the dipole dopant source layer 202 includes a p-type dipole dopant, the dipole dopant source layer 202 may comprise a material selected from one or more of an oxide(s), a nitride(s), and/or a carbide(s) of a p-type dipole dopant(s) such as Al, Zn, Ga, or the like, or combinations thereof. In some embodiments, the dipole dopant source layer 202 comprises a n-type dipole dopant, which when incorporated into the gate dielectrics of n-type FETs, may reduce the effective work functions and hence reduce the threshold voltages of the corresponding n-type FETs. In some embodiments where the dipole dopant source layer 202 includes an n-type dipole dopant, the dipole dopant source layer 202 may comprise a material selected from one or more of an oxide(s), a nitride(s), and/or a carbide(s) of an n-type dipole dopant(s) such as La, Sr, Y, Er, Sc, Mg, or the like, or combinations thereof. The thickness of dipole dopant source layer 202 may be in the range between about 0.5 nm and about 1.2 nm.

In some embodiments as illustrated in FIG. 8, deposition of the dipole dopant source layer 202 is controlled such that the dipole dopant source layer 202 completely fills up the openings 128 between corresponding semiconductor nanostructures 66, and also completely fills up the openings between the lower semiconductor nanostructures 66L and the fins 62. Deposition of the dipole dopant source layer 202 terminates before the dipole dopant source layer 202 entirely fills the gate trenches 126. Upon completion of the deposition, the dipole dopant source layer 202 exhibits a wavy profile in a cross-sectional view, as illustrated in FIG. 8. This wavy configuration of the dipole dopant source layer 202 consequently defines a series of trenches 203, each positioned laterally between pairs of fins 62 and between pairs of overlying semiconductor nanostructures 66. In some embodiments, each trench 203 has a high aspect ratio, e.g., greater than about 16. In some embodiments, the aspect ratio of the trench 203 is a ratio of a trench depth 203H to a trench width 203W. In some embodiments, the aspect ratio of the trench 203 is in a range from about 16 to about 17.

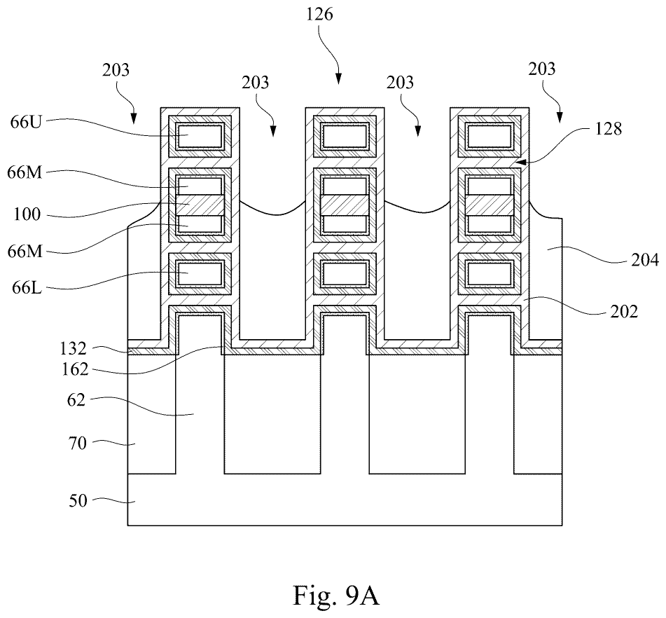

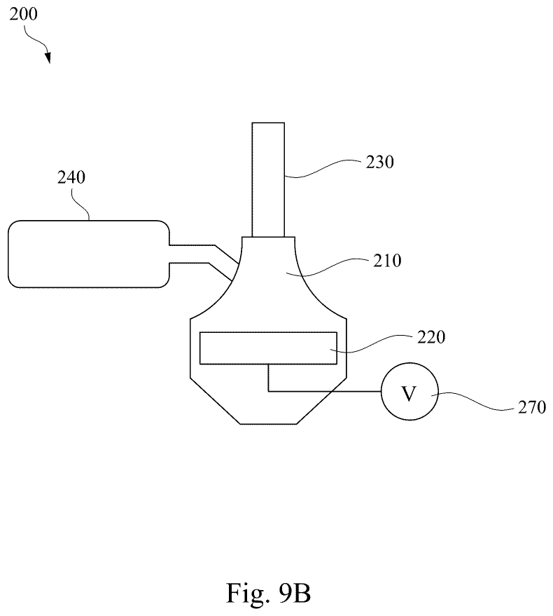

In the subsequent step illustrated in FIG. 9A, a dummy fill material 204 is deposited within the trenches 203 of the dipole dopant source layer 202 through a bottom-up deposition process. In some embodiments, the bottom-up deposition process is performed using a plasma-enhanced flowable chemical vapor deposition (CVD), which utilizes remote plasma source (RPS) or remote capacitively coupled plasma (CCP) along with a bottom bias Radio Frequency (RF) as a co-treatment. The plasma in the CVD process aids in the aggregation of precursor molecules of the dummy fill material 204 into larger clusters, thereby enhancing the bottom-up deposition behavior of the dummy fill material 204. The plasma-enhanced flowable CVD process is controlled, so that a topmost position of the dummy fill material 204 is at a level between the top surface level and the bottom surface level of dielectric isolation nanostructures 100, which allows for defining top ends in a patterned dipole dopant source layer in subsequent processing.

The bottom bias RF is applied to a wafer chuck that holds the substrate 50 using electrostatic force, and hence applies an electrical potential on the substrate 50. The application of an electrical potential on the substrate 50 serves to attract charged clusters dissociated from the dummy fill material precursor, accelerating downward movement of the charged clusters and facilitating the desired bottom-up deposition behavior. Due to the high mass-to-charge ratio of charged clusters, these charged clusters possess significantly greater momentum for a given energy compared to ions or radicals composed of a single or a few atoms with a lower mass per unit charge. This increased momentum enables the charged clusters to deposit effectively at the bottoms of trenches 203, thereby promoting the bottom-up growth behavior.

In some embodiments, a dummy fill material precursor used in the plasma-enhanced flowable CVD may be an organosilicon compound, which is a class of chemical compounds that contain carbon-silicon (C-Si) bonds. These compounds are a significant subset of organometallic chemistry, where silicon, a metalloid, is bonded to organic groups. In some embodiments, the organosilicon compound includes, by way of example and not limitation, trimethylsilane (TSA), tetramethylorthosilicate (TMOS), Methyltrimethoxysilane (MTMS), aminosilane (AMI), cyclooctasiloxane (COSP), octamethylcyclotetrasiloxane (OMCTS), or retramethylcyclotetrasiloxane (TMCTS), in conjunction with an argon (Ar), hydrogen (H₂), and ammonia (NH₃) plasma to deposit the dummy fill material 204, which is derived from the foregoing precursor. Once the CVD process is complete, the deposited dummy fill material 204 remains in a flowable state. The flowability of the as-deposited dummy fill material 204 in the plasma-enhanced flowable CVD process can be attributed to the interaction between the selected precursor compounds and the plasma environment. The foregoing organosilicon precursors are chosen for their ability to form low-viscosity oligomeric or polymeric structures upon exposure to the plasma. The plasma formed from argon (Ar), hydrogen (H₂), and ammonia (NH₃), provides an energetic environment that facilitates the fragmentation of these precursor molecules into reactive species. These reactive species then recombine to form a network of loosely bonded structures, which exhibit flowable characteristics due to their low cross-link density and high degree of molecular mobility.

In some embodiments, the presence of hydrogen and ammonia in the plasma may aid in maintaining the flowability of the deposited material. Hydrogen can act as a reducing agent, preventing excessive cross-linking by terminating reactive sites with hydrogen atoms, thereby preserving the as-deposited dummy fill material's flowable nature. In some embodiments, ammonia can introduce nitrogen into the network, which may contribute to the formation of flexible Si-N or C-N bonds, further enhancing the material's ability to flow. Additionally, the argon component of the plasma can serves as an inert carrier gas, ensuring uniform distribution of the reactive species across the dipole dopant source layer 202, which aids in achieving a consistent deposition of the flowable material. The flowable state of the dummy fill material 204 is advantageous for filling the trenches 203 with a high aspect ratio (e.g., greater than about 16).

FIG. 9B is a schematic diagram of an example deposition apparatus 200 for performing the plasma-enhanced flowable CVD, in accordance with some embodiments of the present disclosure. In some embodiments, the deposition apparatus 200 includes a process chamber 210, a wafer chuck 220, a plasma source 230, and a precursor delivery 240. The wafer chuck 220 is in the process chamber 210, and the plasma source 230 and the precursor delivery 240 are connected to the process chamber 210.

The plasma source 230 may be a remote plasma source (RPS) or a remote capacitively coupled plasma (CCP) source, which is separated from the processing chamber 210. Plasma source gases (e.g., Ar, H₂ and/or NH₃ gases) may be introduced into the plasma source 230 and excited to create plasma. In some embodiments, these gases are exited using microwaves to create the plasma. The microwaves are generated using a microwave oscillator and are introduced into the plasma source 230 using an optical waveguide. The plasma in the plasma source 230 is then fed through a conduit into the processing chamber 210.

In some embodiments, the deposition apparatus 200 further includes a bias source 270 connected to the chuck 220. The bias source 270 serves apply a bias to the wafer chuck 220 and thus to the wafer positioned thereon. In some embodiments, the bias source 270 can apply DC and/or RF bias to the chuck 220. In some embodiments, the bias source 270 serves to apply a bias to the wafer chuck 220 to attract the charged clusters of the dummy fill material precursor toward the substrate 50, facilitating the bottom-up deposition behavior.

In some embodiments, the operational sequence begins with the activation of the bias source 270 prior to the initiation of the plasma source 230. This sequence can establish an electrical potential across the substrate 50 before the introduction of plasma into the process chamber 210. By applying the bias voltage first, bottoms of the trenches 203 are prepared to receive more effectively with the incoming plasma. In some embodiments, the precursor delivery 240 is activated following the initiation of the plasma source 230. This timing sequence allows that precursor gases are introduced into an environment already containing plasma within the process chamber 210. The presence of plasma before the introduction of precursor gases facilitates the immediate activation and dissociation of these gases.

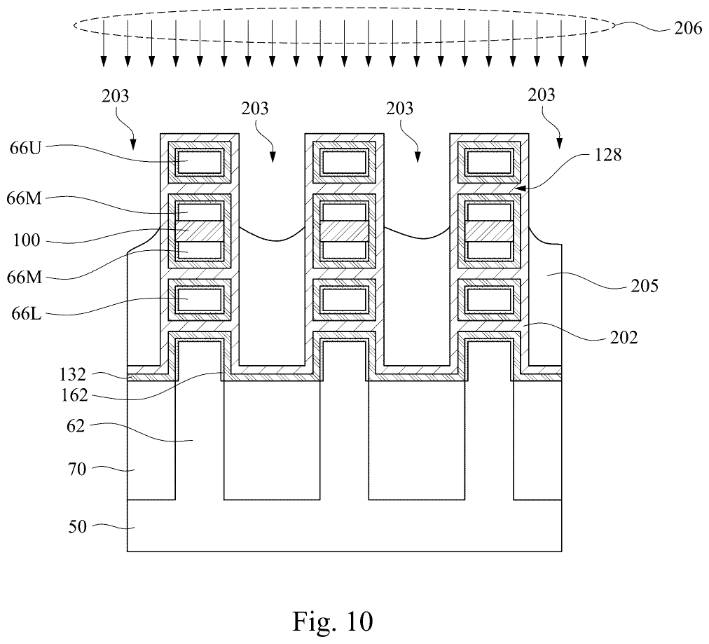

Next, in FIG. 10, once the plasma-enhanced flowable CVD process is complete, the dummy fill material 204 is converted from the flowable state into a non-flowable state by using a curing treatment 206. The curing treatment 206 solidifies the flowable dummy fill material 204 into a non-flowable dummy filled material 205. In some embodiments, the curing treatment 206 includes, for example, an ultraviolet (UV) curing treatment and/or a thermal curing treatment. The thermal curing treatment can facilitate the cross-linking of polymer chains within the flowable material, thereby enhancing its structural integrity and transforming it into a solidified form. The UV curing treatment involves exposing the flowable dummy fill material 204 to UV radiation. This exposure induces photochemical reactions within the flowable dummy fill material 204, further promoting cross-linking and densification.

After curing, the dummy fill material 205 exhibits a concave top surface profile. This concave shape results from the material's flowability during deposition. In some embodiments, the cured dummy fill material 205 may include compositions such as silicon carbon oxide (SiCO), silicon carbon oxynitride (SiCON), silicon oxide (SiOx), carbon, and so on. The dummy fill material 205 is formed from plasma enhanced flowable CVD without performing any CMP process, and thus the CMP over-polishing issues in existing methods of forming dummy fill material can be mitigated.

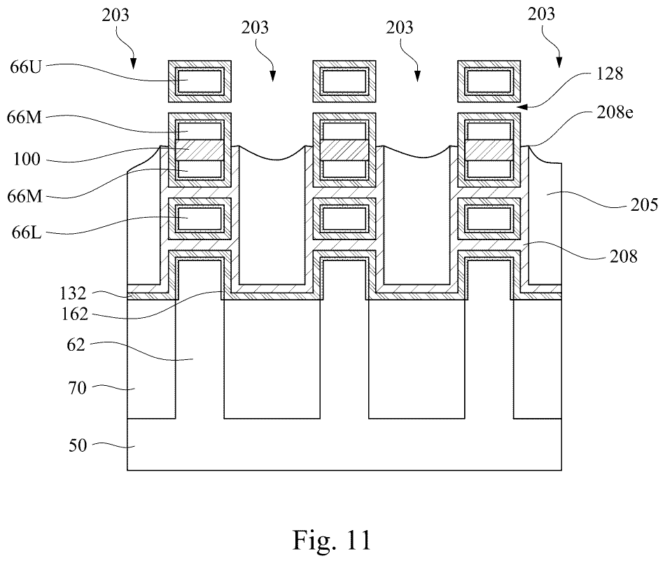

Next, in FIG. 11, the dipole dopant source layer 202 is patterned into patterned dipole dopant source layers 208 by using the dummy fill material 205 as an etch mask. Specifically, in some embodiments, upper portions of the dipole dopant source layer 202 exposed by the dummy fill material 205 is removed by using, for example, a selective etching process, while leaving lower portions of the dipole dopant source layer 202 protected by the dummy fill material 205. The etching chemical is selected to etch dipole dopant source layer 202, and stops on the gate dielectric layers 132. Accordingly, the portions of dipole dopant source layer 202 on upper semiconductor nanostructures 66U and the upper one of the middle semiconductor nanostructures 66M are removed. The portions of dipole dopant source layer 202 on lower semiconductor nanostructures 66L and the lower one of the middle semiconductor nanostructures 66M are protected by the cured dummy fill material 205 from being removed. The remaining portions of dipole dopant source layer 202 are collectively referred to as patterned dipole dopant source layers 208. The patterned dipole dopant source layers 208 each have a U-shaped cross-sectional profile with top ends 208e at a level between the top surface level and the bottom surface level of dielectric isolation nanostructures 100.

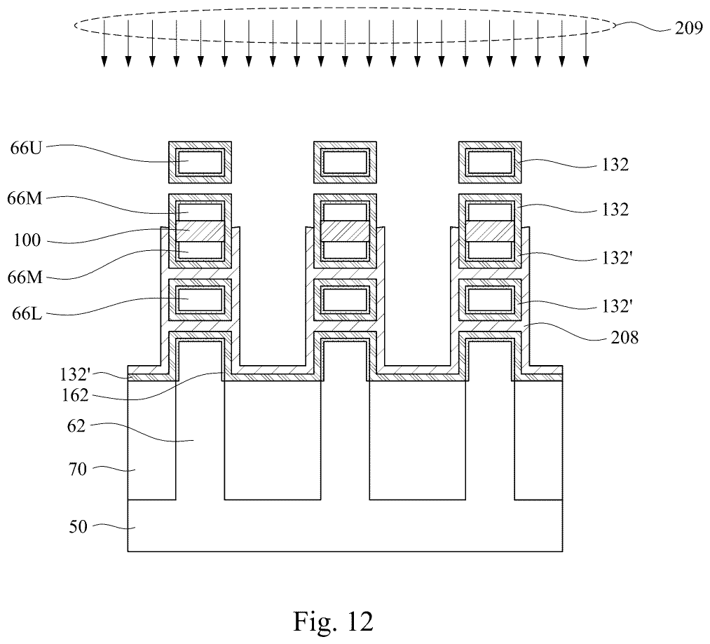

Next, the dummy fill material 205 is removed. The resulting structure is shown in FIG. 12. After the removal of dummy fill material 205, the dipole dopant source layers 208 in the lower FET region are exposed, while in the upper FET region, there is no dipole dopant source layer.

Next, an anneal process 209 is performed to carry out a solid-phase thermal diffusion process that drives/diffuses the dipole dopants from the patterned dipole dopant source layers 208 into the respective underlying gate dielectric layers 132. The resulting gate dielectric layers 132 with the dipole dopant incorporated are referred to as dipole-doped gate dielectric layers 132′ hereinafter. Upper gate dielectric layers 132 not covered by the dipole dopant source layers 208 may remain un-doped in the anneal process 209. The anneal process 209 may be performed in a process gas such as N₂, He, NH₃, Ar, or the like, or the mixture thereof. In accordance with some embodiments, anneal process 209 is performed through a soak anneal process, a spike rapid thermal anneal process, or the like. In some embodiments, the annealing temperature may be in a range between about 550° C. and about 800° C.

Upon completion of the anneal process 209, the dipole-doped gate dielectric layers 132′ have a dipole dopant atomic percentage greater than the dipole dopant atomic percentage in the upper gate dielectric layers 132. In some embodiments, the upper gate dielectric layer 132 may be free from the dipole dopant. In some embodiments, the difference in dipole dopant atomic percentages between the dipole-doped gate dielectric layers 132′ and the upper gate dielectric layers 132 may be greater than about 1 percent, and may be in the range between about 15 percent. The desirable dipole dopant atomic percentage depends on the desirable threshold voltage of the resulting lower nanostructure-FET. The desirable dipole dopant atomic percentage can be achieved by adjusting the thickness of dipole dopant source layer 202, and the greater the thickness is, the higher the dipole dopant atomic percentage is.

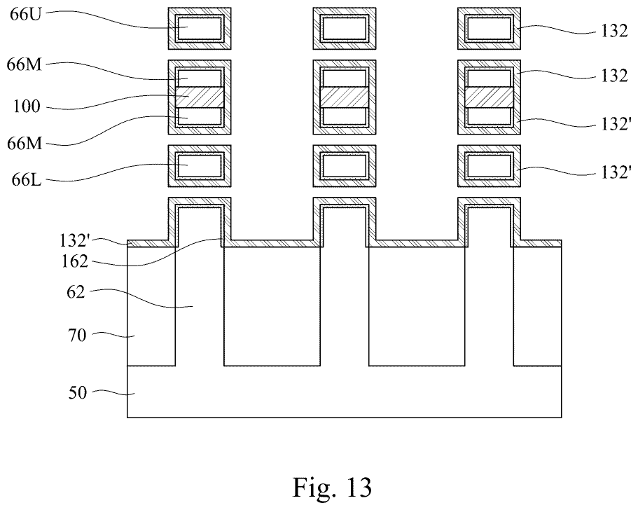

Next, the patterned dipole dopant source layers 208 are removed in a selective etching process that etches the material of the patterned dipole dopant source layers 208 but hardly attacks the material of the gate dielectric layers 132, 132'. Therefore, the gate dielectric layers 132 and 132′ remain intact during the etching process. The resulting structure is shown in FIG. 13, wherein the un-doped upper gate dielectric layers 132 and the dipole-doped lower gate dielectric layers 132′ are exposed.

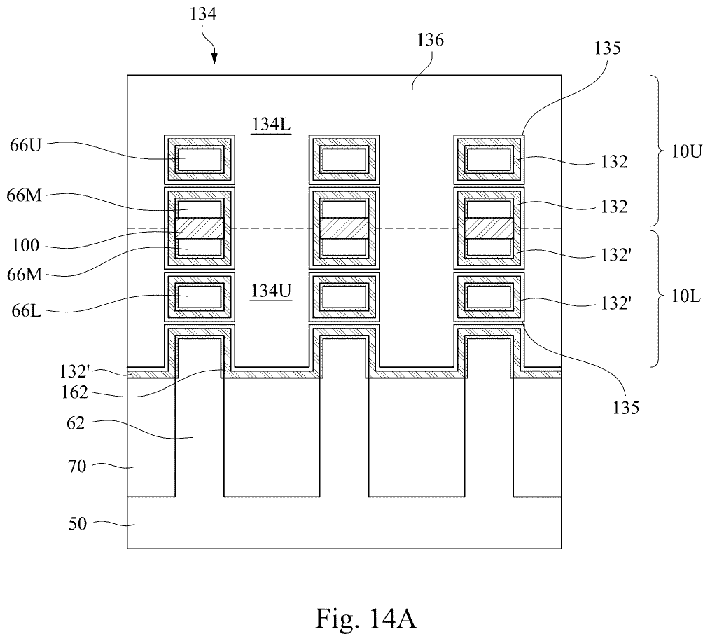

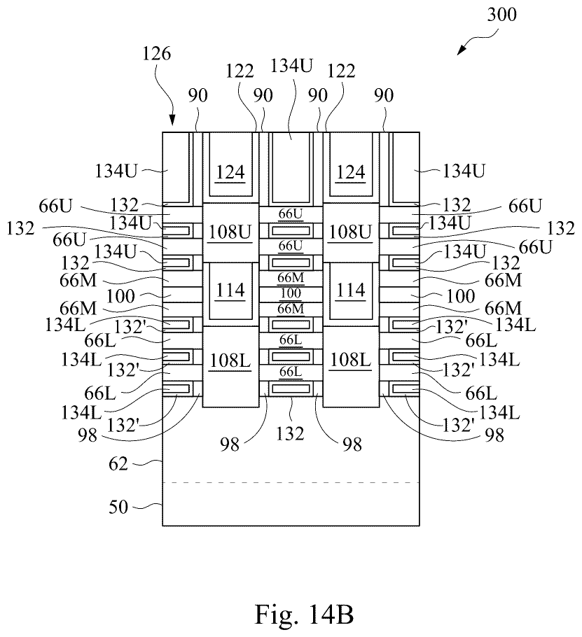

FIGS. 14A and 14B illustrates the formation of gate electrodes in common processes for an upper FET 10U and a lower FET 10L. The resulting upper FET 10U and lower FET 10L share a common gate electrode 134. The upper portion of the gate electrode 134 that is higher than isolation nanostructures 100 is referred to as upper gate electrode 134U. The lower portion of the gate electrode 134 that is lower than isolation nanostructures 100 is referred to as lower gate electrode 134L.

In some embodiments, the gate electrodes 134 each may include one or more work function layers 135 surrounding the dipole-doped gate dielectric layers 132′ and the un-doped gate dielectric layers 132, and a fill metal 136 surrounding the one or more work function layers. In some embodiments, the work function layers 135 and the interfacial layer 162 illustrated in FIG. 14A are not illustrated in FIG. 14B for the sake of clarity.

In some embodiments, the fill metal 136 may comprise tungsten, ruthenium, cobalt, combinations thereof, multi-layers thereof, or the like. In some embodiments, the work function layers 135 encircling each of the gate dielectric layers 132 and 132′ may be physically separate from the work function layers 135 encircling other ones of the gate dielectric layers 132 and 132′. In which case, the fill metal 136 (such as tungsten, ruthenium, cobalt, or the like) may fill the spaces between the work function layers 135 on neighboring ones of the gate dielectric layers 132 and 132'. Alternatively, the work function layers 135 encircling each of the gate dielectric layers 132 and 132′ may be physically joined to the work function layers 135 encircling other ones of the gate dielectric layers 132 and 132'. In some embodiments, the gate electrodes 134 can be formed by, for example, depositing the work function layers 135 surrounding the dipole-doped gate dielectric layers 132′ and the un-doped gate dielectric layers 132, depositing the fill metal 136 to overfill the gate trenches 126, followed by performing a CMP step on the fill metal 136 to remove excess materials of the work function layers 135 and the fill metal 136 outside the gate trenches 126 until the gate spacers 90 and the second ILD 124 are exposed.

In some embodiments, the work function layers 135 have a p-type work function, which is higher than about 4.6 eV, and may be in the range between about 4.6 eV and about 5.2 eV. The p-type work function metal in the work function layers 135 for providing p-type work function may exemplarily include, but are not limited to, titanium nitride (TiN), tungsten nitride (WN), tungsten (W), ruthenium (Ru), palladium (Pd), platinum (Pt), cobalt (Co), nickel (Ni), conductive metal oxides, and/or other suitable materials. In some other embodiments, the work function layer 135 has an n-type work function lower than about 4.5 eV, and may be in the range between about 4.0 eV and about 4.5 eV. The n-type work function metal in the work function layers 135 for providing n-type work function may exemplarily include, but are not limited to, titanium aluminide (TiAl), titanium aluminium nitride (TiAlN), aluminum (Al), aluminum nitride (AlN), and/or other suitable materials.

In some embodiments, the lower FET 10L and the upper FET 10U have the same number and composition of work function layers 135, such as the same number and composition n-type work function metal layers. However, in scenarios where the upper FET 10U is configured as an n-type FET and the lower FET 10L as a p-type FET, a challenge arises. The p-type FET is operated under p-type work functions, which has a higher work function value than the work function value of the n-type work function metal layer. This conflict can be solved by doping the gate dielectric layers of the PFETs with a p-type dipole dopant, as discussed above, so that the effective work function of the n-type work function layers in the PFETs is increased to the p-type work function range, for example, between about 4.6 eV. The NFET's gate dielectric layers, on the other hand, are not doped with the p-type dipole dopant, and hence the NFET's work function layers remain to have an n-type effective work function.

In some embodiments, the lower FET 10L and the upper FET 10U have the same number and composition of work function layers 135, such as the same number and composition p-type work function metal layers. However, in scenarios where the upper FET 10U is configured as a p-type FET and the lower FET 10L as an n-type FET, a challenge arises. The n-type FET is operated under n-type work functions, which has a lower work function value than the work function value of the p-type work function metal layer. This conflict can be solved by doping the gate dielectric layers of the NFETs with an n-type dipole dopant, as discussed above, so that the effective work function of the p-type work function layers in the NFETs is reduced to the n-type work function range, for example, between about 4.0 eV and about 4.5 eV. The PFET's gate dielectric layers, on the other hand, are not doped with the n-type dipole dopant, and hence the PFET's work function layers remain to have a p-type effective work function.

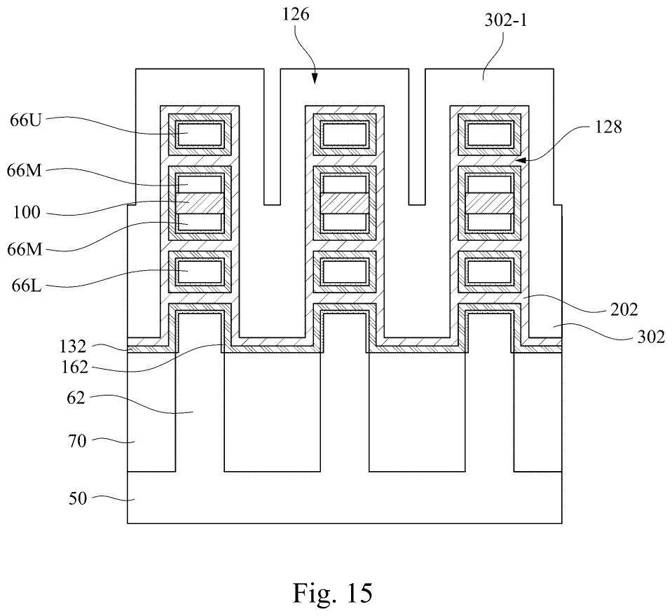

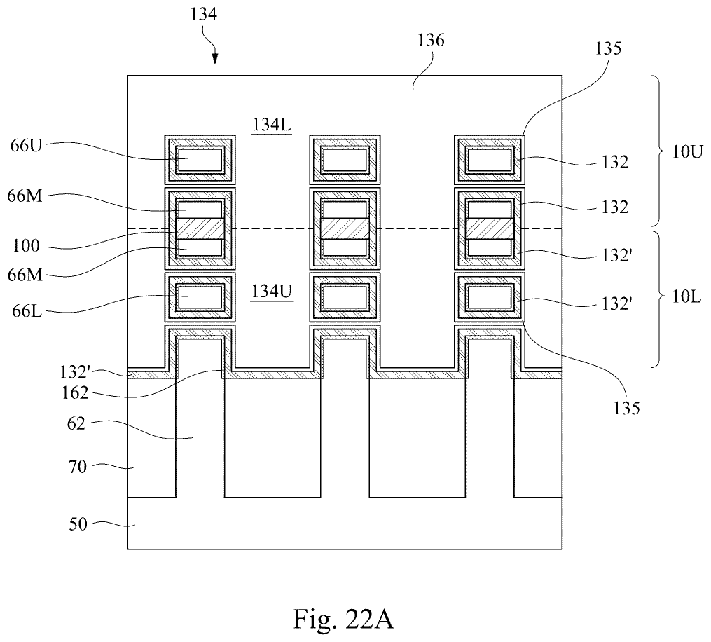

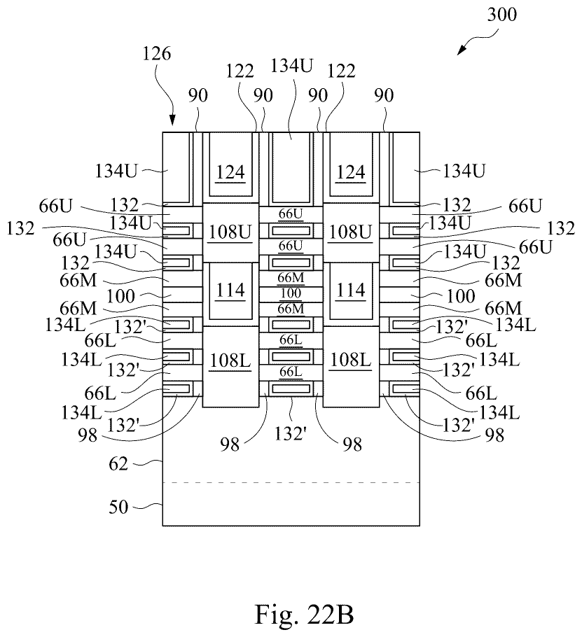

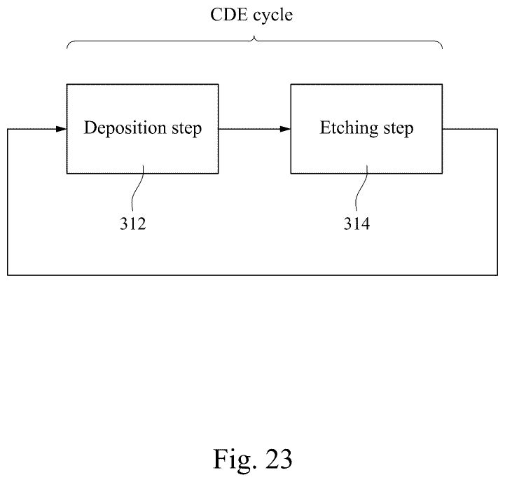

FIGS. 15-22B are cross-sectional views of a CFET device at various stages of manufacturing, in accordance with some other embodiments of the present disclosure. FIGS. 15-22A illustrate cross-sectional views along a similar cross-section as reference cross-section B-B′ in FIG. 1. FIG. 22B illustrates cross-sectional views along a similar cross-section as reference cross-section A-A′ in FIG. 1. Illustrated in FIGS. 15-18 is another bottom-up growth approach to form a bottom-up dummy fill material without subjecting the bottom-up fill material to any CMP process. In particular, the bottom-up growth approach is a cyclic deposition and etching (CDE) process including one or more repetitions of a CDE cycle, wherein each CDE cycle includes a deposition step 312 followed by an etching step 314, as illustrated in the flow chart in FIG. 23.

FIG. 15 illustrates a deposition step 312 of an initial CDE cycle, which is performed after forming the dipole dopant source layer 202 as illustrated FIG. 8. In some embodiments, the initial step includes loading the substrate 50 covered with the dipole dopant source layer 202 into a plasma-enhanced chemical vapor deposition (PECVD) chamber equipped with a capacitively coupled plasma (CCP) RF generator. The chamber is evacuated to a suitable pressure to ensure a controlled environment for the subsequent CDE cycles. At the deposition step 312 of the initial CDE cycle, a precursor gas is introduced into the PECVD chamber. The RF generator is activated to create a plasma environment, which facilitates the dissociation of the precursor gas molecules. This dissociation results in the formation of reactive species that deposit onto the dipole dopant source layer 202, forming an initial dummy material layer 302-1 of a dummy fill material 302, which is a continuous layer covering an entirety of the dipole dopant source layer 202. In some embodiments, the precursor gas includes, for example, C₂H₂, C₃H₆, bis(diethylamino)silane (i.e., SAM-24), and/or SiH₄. The initial dummy material layer 302-1 may include, for example, carbon or SiO, depending on the precursor used in the deposition step 312. The deposition step 312 terminates prior to the initial dummy material layer 302-1 completes filling the gate trench 126. Stated differently, the deposition step 312 stops when the initial dummy material layer 302-1 partially fills the gate trench 126.

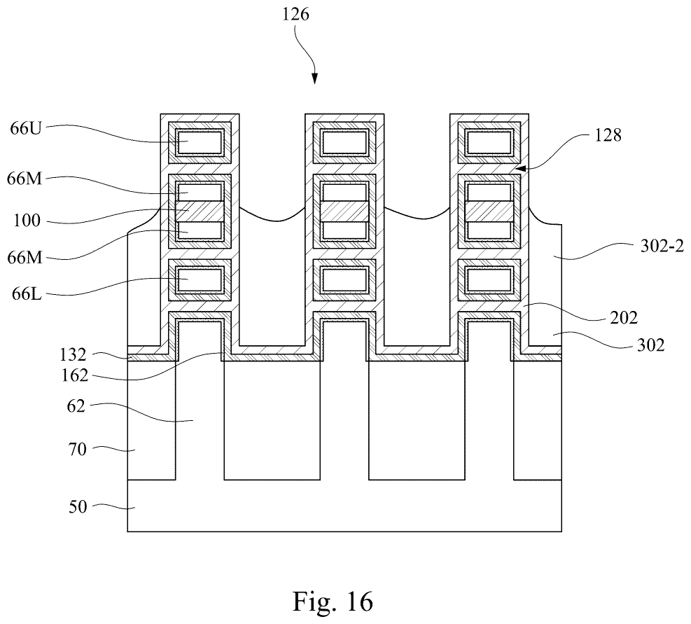

FIG. 16 illustrates an etching step 314 of the initial CDE cycle. In some embodiments, as illustrated in FIG. 16, following the deposition step 312, an etching step 314 is initiated. In some embodiments, the etching step 314 is in-situ performed after performing the deposition step 312. In the in-situ etching step 314, an etchant gas, which is different than the precursor gas used in the deposition step 312, is introduced into the chamber in which the previous deposition step 312 is performed. The RF generator is activated, applying an RF electromagnetic field to ionizing the etchant gas molecules into an etching plasma. The etching plasma contains reactive species, such as ions and radicals, which selectively interact with the initial dummy material layer 302-1. This interaction results in the selective removal of initial dummy material layer 302-1, particularly from upper regions in the gate trenches 126. In some embodiments, the etchant gas is selected such that the etching step 314 selectively etches the initial dummy material layer 302-1 without etching the dipole dopant source layer 202. The selective etchant gas includes, for example, H₂, CF₄, or other suitable gas. The etching step 314 is performed such that the continuous initial dummy material layer 302-1 is etched back into discontinuous dummy material layers 302-2, which are separated by the dipole dopant source layer 202. In some embodiments, each dummy material layer 302-2 has a different top surface profile than the initial dummy material layer 302-1. For example, the top surface of the each dummy material layer 302-2 is more curved than the top surface of the initial dummy material layer 302-1. In some embodiments, each dummy material layer 302-2 has a concave top surface resulting from the in-situ etching step 314.

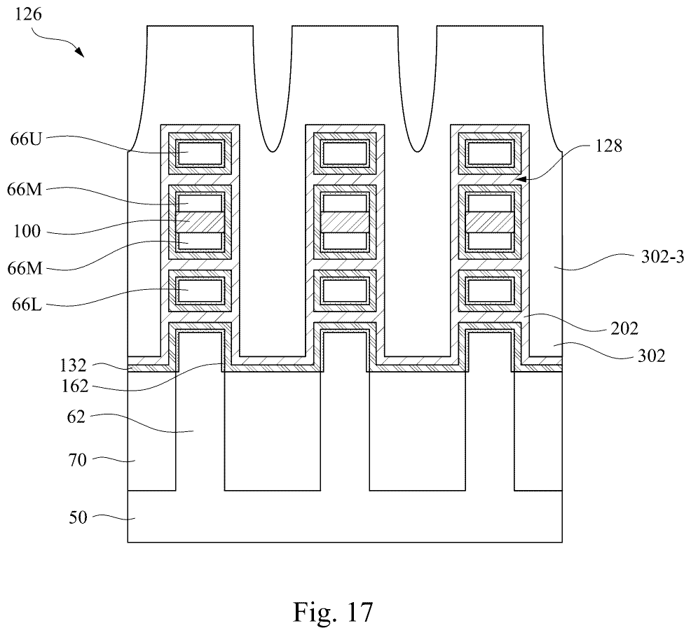

Following completion of the initial CDE cycle, a deposition step 312 of a next CDE cycle is performed, as illustrated in FIG. 17. In some embodiments, the deposition step 312 of the next CDE cycle has substantially the same process conditions that of the initial CDE cycle. For example, the deposition step 312 of the next CDE cycle uses the same precursor gas as that of the initial CDE cycle, and thus deposits the same material as that deposited by the initial CDE cycle. The deposition step 312 of the next CDE cycle continues until a continuous dummy material layer 302-3 is formed, covering the entire dipole dopant source layer 202 again. The deposition step 312 of the next CDE cycle terminates prior to the dummy material layer 302-3 completes filling the gate trench 126. Stated differently, the deposition step 312 of the next CDE cycle stops when the dummy material layer 302-3 partially fills the gate trench 126. In some embodiments, the dummy material layer 302-3 includes concave recesses, due to the concave top surface of the precedent dummy material layer 302-2.

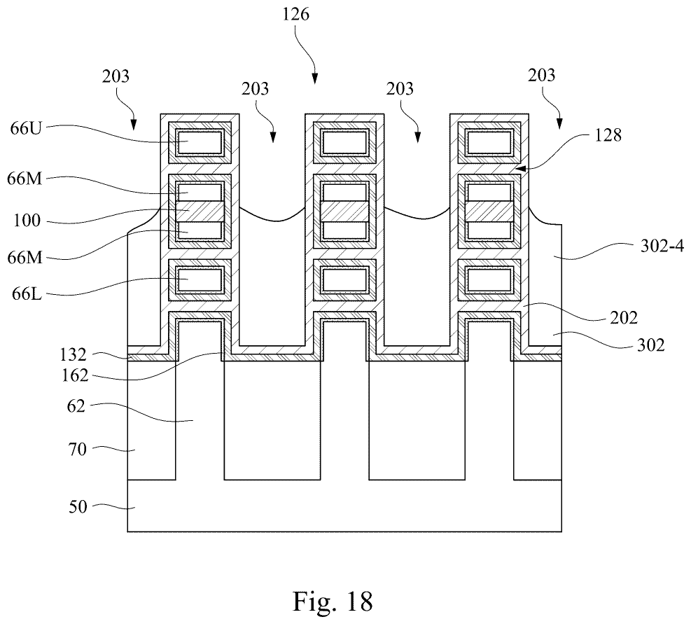

FIG. 18 illustrates an etching step 314 of the next CDE cycle. Similar to the etching step 314 of the previous CDE cycle, the etching step 314 can be in-situ performed after performing the deposition step 312. In the in-situ etching step 314, an etchant gas, which is different than the precursor gas used in the deposition step 312, is introduced into the chamber in which the previous deposition step 312 is performed. The RF generator is activated, applying an RF electromagnetic field to ionizing the etchant gas molecules into an etching plasma, which can selectively remove the dummy material layer 302-3, particularly from upper regions in the gate trenches 126. In some embodiments, the etchant gas is selected such that the etching step 314 selectively etches the dummy material layer 302-3 without etching the dipole dopant source layer 202. The selective etchant gas includes, for example, H₂, CF₄, or other suitable gas. The etching step 314 is performed such that the continuous dummy material layer 302-3 is etched back into discontinuous dummy material layers 302-4, which are separated by the dipole dopant source layer 202. In some embodiments, each dummy material layer 302-4 has a different top surface profile than the precedent dummy material layer 302-3. For example, the top surface of the each dummy material layer 302-4 has a different curvature than the top surface of the precedent dummy material layer 302-3. In some embodiments, each dummy material layer 302-4 has a concave top surface resulting from the in-situ etching step 314.

The CDE cycle is repeated until the discontinuous dummy material layers (such a the discontinuous dummy material layers 302-4) have topmost positions reaching a target level height. The resultant dummy material layers 302-4 can be collectively referred to as a CDE-formed dummy fill material 302. For example, as illustrated in FIG. 18, the dummy material layers 302-4 have topmost positions at a level between the top surface level and the bottom surface level of dielectric isolation nanostructures 100, which allows for defining top ends in a patterned dipole dopant source layer in subsequent processing. While FIGS. 15-18 illustrate a scenario involving two CDE cycles, it is possible to perform additional CDE cycles in other embodiments to achieve the desired material layer configuration. The dummy fill material 302 is formed from the CDE cycles without performing any CMP process, and thus the CMP over-polishing issues in existing methods of forming dummy fill material can be mitigated.

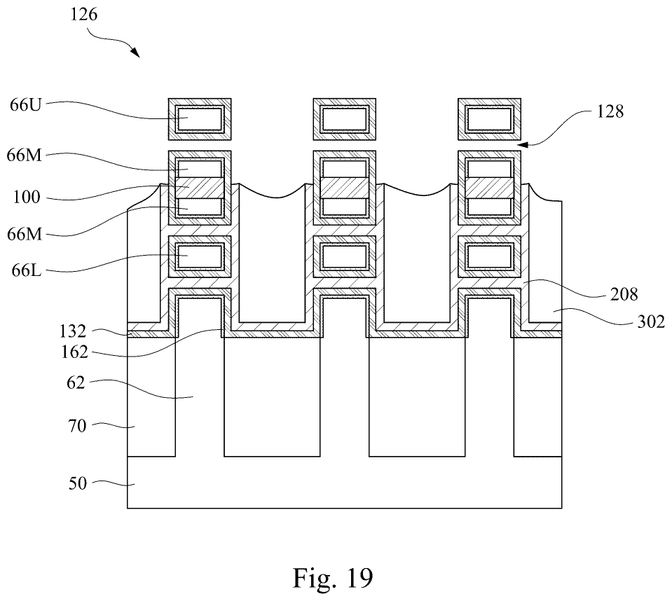

Next, in FIG. 19, the dipole dopant source layer 202 is patterned into patterned dipole dopant source layers 208 by using the dummy fill material 302 as an etch mask. Specifically, in some embodiments, upper portions of the dipole dopant source layer 202 exposed by the dummy fill material 302 are removed by using, for example, a selective etching process, while leaving lower portions of the dipole dopant source layer 202 protected by the dummy fill material 302. The etching chemical is selected to etch dipole dopant source layer 202, and stops on the gate dielectric layers 132. Accordingly, the portions of dipole dopant source layer 202 on upper semiconductor nanostructures 66U and the upper one of the middle semiconductor nanostructures 66M are removed. The portions of dipole dopant source layer 202 on lower semiconductor nanostructures 66L and the lower one of the middle semiconductor nanostructures 66M are protected by the dummy fill material 302 from being removed. The remaining portions of dipole dopant source layer 202 are collectively referred to as patterned dipole dopant source layers 208. The patterned dipole dopant source layers 208 each have a U-shaped cross-sectional profile with top ends at a level between the top surface level and the bottom surface level of dielectric isolation nanostructures 100.

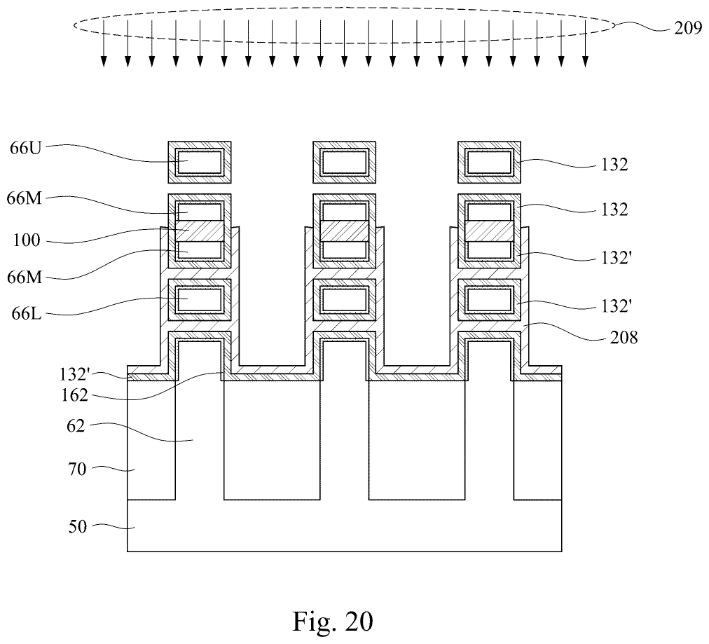

Next, the dummy fill material 302 is removed. The resulting structure is shown in FIG. 20. After the removal of dummy fill material 302, the dipole dopant source layers 208 in the lower FET region are exposed, while in the upper FET region, there is no dipole dopant source layer.

Next, an anneal process 209 is performed to drive the dipole dopants in the patterned dipole dopant source layers 208 into the respective underlying gate dielectric layers 132. The resulting gate dielectric layers 132 with the dipole dopant incorporated are referred to as dipole-doped gate dielectric layers 132′ hereinafter. Upper gate dielectric layers 132 not covered by the dipole dopant source layers 208 may remain un-doped in the anneal process 209. Other details regarding the annealing process 209 are discussed previous with respect to FIG. 12 and thus are not repeated for the sake of brevity.

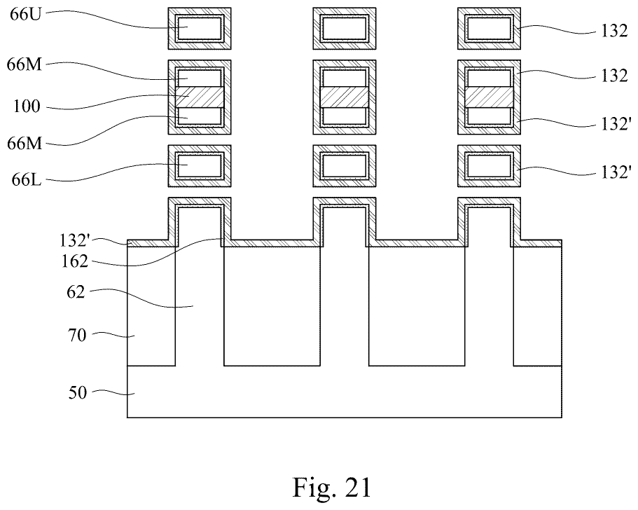

Next, the patterned dipole dopant source layers 208 are removed in a selective etching process that etches the material of the patterned dipole dopant source layers 208 but hardly attacks the material of the gate dielectric layers 132, 132′. Therefore, the gate dielectric layers 132 and 132′ remain intact during the etching process. The resulting structure is shown in FIG. 21, wherein the un-doped upper gate dielectric layers 132 and the dipole-doped lower gate dielectric layers 132′ are exposed.

FIGS. 22A and 22B illustrates the formation of gate electrodes in common processes for an upper FET 10U and a lower FET 10L. The resulting upper FET 10U and lower FET 10L share a common gate electrode 134. The upper portion of the gate electrode 134 that is higher than isolation nanostructures 100 is referred to as upper gate electrode 134U. The lower portion of the gate electrode 134 that is lower than isolation nanostructures 100 is referred to as lower gate electrode 134L. In some embodiments, the gate electrodes 134 each may include one or more work function layers 135 surrounding the dipole-doped gate dielectric layers 132′ and the un-doped gate dielectric layers 132, and a fill metal 136 surrounding the one or more work function layers. Other details regarding the gate electrodes 134 are discussed previously with respect to FIGS. 14A and 14B and thus are not repeated for the sake of brevity.

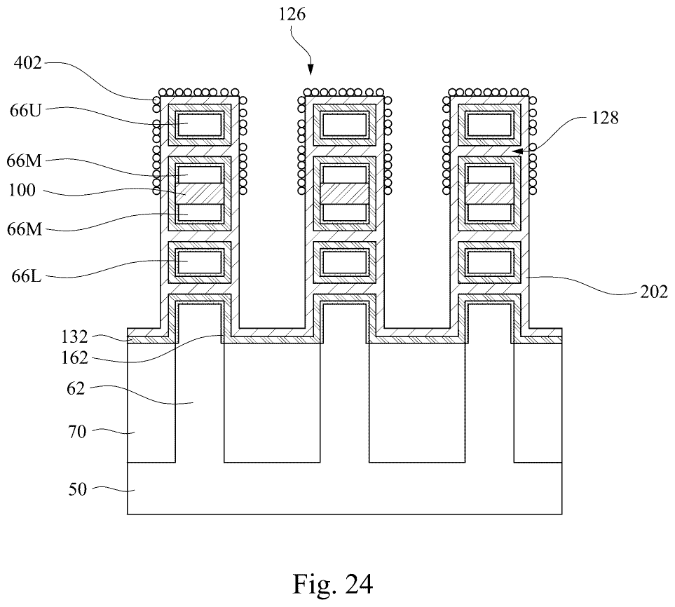

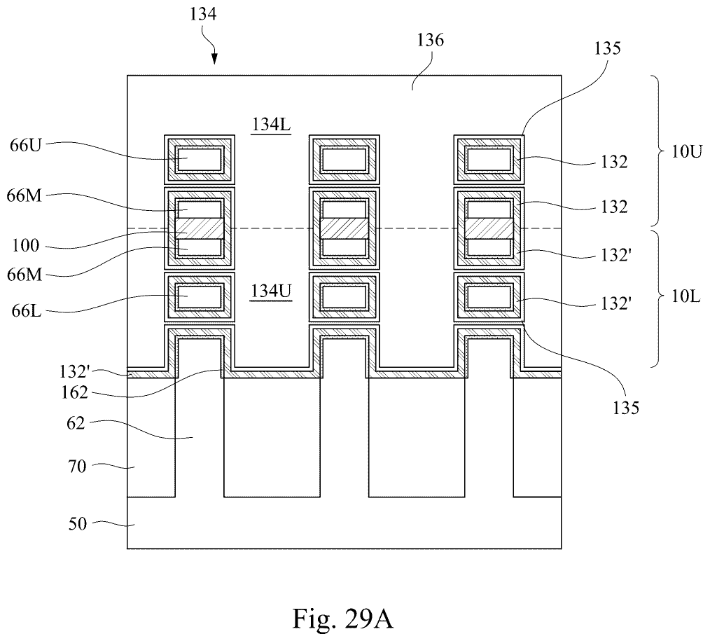

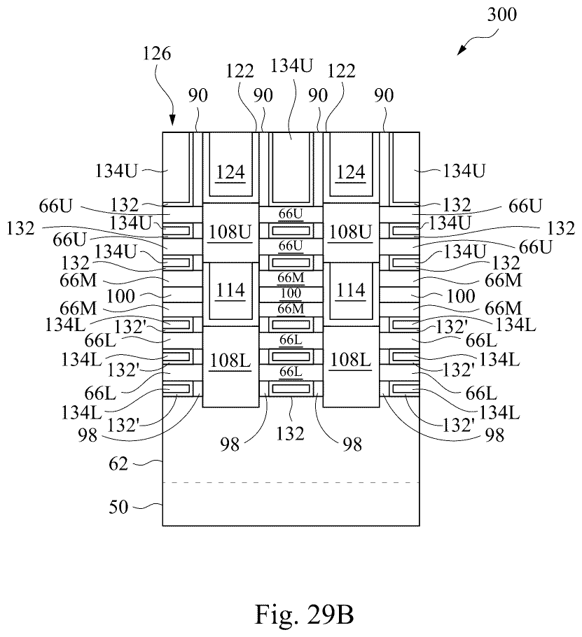

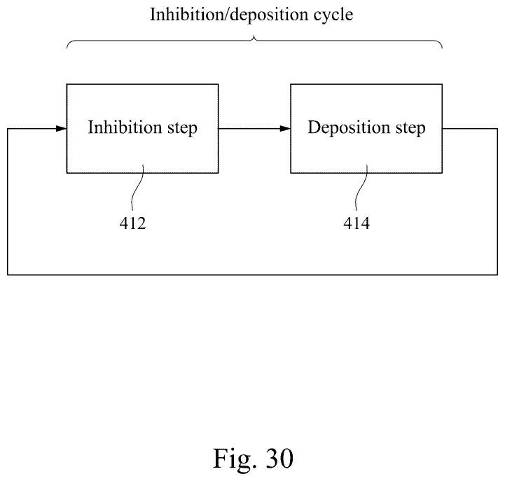

FIGS. 24-29B are cross-sectional views of a CFET device at various stages of manufacturing, in accordance with some other embodiments of the present disclosure. FIGS. 24-29A illustrate cross-sectional views along a similar cross-section as reference cross-section B-B′ in FIG. 1. FIG. 29B illustrate cross-sectional views along a similar cross-section as reference cross-section A-A′ in FIG. 1 Illustrated in FIGS. 24-26 is another bottom-up growth approach to form a bottom-up dummy fill material without performing any CMP process on the dummy fill material. In particular, the bottom-up growth approach is a cyclic inhibition and deposition process including one or more repetition of an inhibition/deposition cycle, wherein each inhibition/deposition cycle includes an inhibition step 412 followed by a deposition step 414, as illustrated in the flow chart in FIG. 30. In the inhibition step 412, inhibitors are formed selectively on upper regions of gate trenches, such that in the subsequent deposition step 414, the dummy fill material can be deposited at lower regions of the gate trenches.

FIG. 24 illustrates an inhibition step 412 of an initial inhibition/deposition cycle, which is performed after forming the dipole dopant source layer 202 as illustrated FIG. 8. In some embodiments, the initial step includes loading the substrate 50 covered with the dipole dopant source layer 202 into a plasma-enhanced chemical vapor deposition (PECVD) chamber equipped with a capacitively coupled plasma (CCP) RF generator. The chamber is evacuated to a suitable pressure to ensure a controlled environment for subsequent processing. Next, a plasma treatment is performed on the dipole dopant source layer 202. Inhibition radicals generated from the plasma treatment bond to upper portions of the dipole dopant source layer 202 to serve as inhibitors 402, which can inhibit dummy material nucleation on the upper portions of the dipole dopant source layer 202, thereby allowing the dummy material to be selectively grow from lower portions of the dipole dopant source layer 202 in subsequent processing, without growing from the upper portions of the dipole dopant source layer 202.

In some embodiments, the plasma treatment is performed using a hydrogen plasma generated from an H₂ gas, and/or a nitrogen plasma generated from an N₂ gas. In some embodiments, the plasma source gas (e.g., H₂ gas and/or N₂ gas) is introduced into the chamber. The RF generator is activated, applying an RF electromagnetic field to ionizing the plasma source gas molecules into inhibitor plasma (e.g., hydrogen plasma and/or nitrogen plasma). Hydrogen radicals and/or nitrogen radicals in the inhibitor plasma then absorb to and bond to the upper portions of the dipole dopant source layer 202 to form inhibitors 402. The lower portions of the dipole dopant source layer 202 remain free of inhibitors 402 because the inhibition radicals do not migrate to these regions. This area selective inhibitor formation can be controlled by adjusting the process conditions of the plasma treatment, such as the pressure in the chamber, and/or the RF power applied to the CCP RF generator. In some embodiments, the process conditions of the plasma treatment are controlled in such a way that the lower portions of the dipole dopant source layer 202 below the bottom surface level of dielectric isolation nanostructures 100 are free from inhibitors 402, while the upper portions of the dipole dopant source layer 202 above the bottom surface level of dielectric isolation nanostructures 100 are bonded with the inhibitors 402.

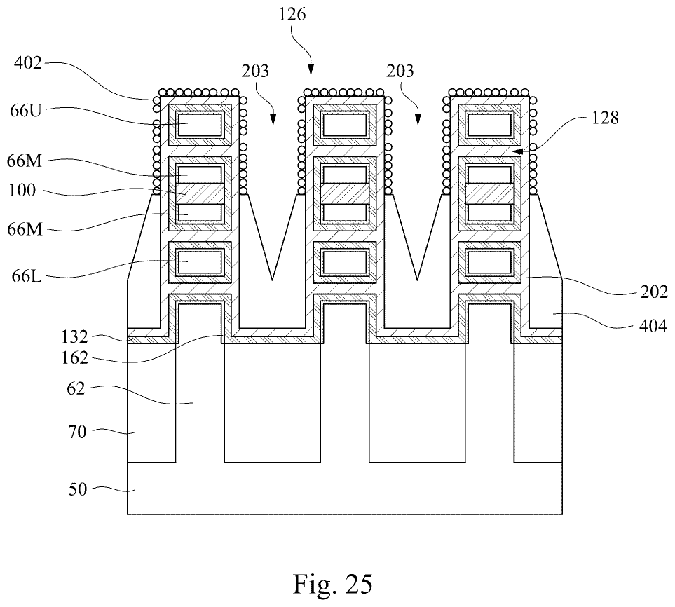

FIG. 25 illustrates a deposition step 414 of the initial inhibition/deposition cycle. In some embodiments, after forming the inhibitors 402 on the upper portions of the dipole dopant source layer 202, a dummy fill material 404 is selective deposited on the lower portions of the dipole dopant source layer 202. This selective deposition is facilitated by the presence of inhibitors 402, which effectively prevent the nucleation and growth of the dummy fill material 404 on the upper portions of the dipole dopant source layer 202. In some embodiments, the dummy fill material 404 includes, for example, carbon, silicon nitride (SiN), silicon oxide (SiOx), silicon carbon oxide (SiCO) or the like, and is deposited using precursors, such as acetylene (C₂H₂), propylene (C₃H₆), silane (SiH₄), or the like. The dummy fill material 404 has a faster deposition rate on the lower portion of the dipole dopant source layer 202 than on the inhibitors 402. The inhibitors 402 inhibit the deposition from occurring on the upper portions of the dipole dopant source layer 202. The deposition duration is controlled such that the deposition terminates before nucleation of the dummy fill material 404 occurs on the inhibitors 402. This allows that the dummy fill material 404 remains confined to the lower portions of the dipole dopant source layer 202, where the absence of inhibitors 402 allows for unhindered deposition. The selection of precursors, such as C₂H₂, C₃H₆, and SiH₄, is advantageous for the selective deposition as these precursors are susceptible to the inhibitory effects of the inhibitors 402 bonded to the upper portions of the dipole dopant source layer 202.

Upon completion of the initial inhibition/deposition cycle, the cycle can be repeated iteratively until the dummy fill material 404 reaches a target thickness that is thick enough to protect the lower portions of the dipole dopant source layer 202 in subsequent patterning process. Once all inhibition/deposition cycles are completed, the final dummy fill material 404 has a topmost position that is located between the top surface level and the bottom surface level of the dielectric isolation nanostructures 100. This positioning facilitates the definition of top ends in the patterned dipole dopant source layers during subsequent processing steps.

In some embodiments, the resultant dummy fill material 404 has a series of V-shaped top surfaces respectively in the trenches 203 in the dipole dopant source layer 202. This V-shaped profile arises due to the diminishing inhibitory effect of the inhibitors 402 as the deposition precursors penetrate deeper into the trenches 203. As the precursors move further into these trenches 203, the influence of the inhibitors 402 weakens, allowing for a more pronounced deposition in these deeper regions. This results in the V-shaped surfaces of the dummy fill material 404.

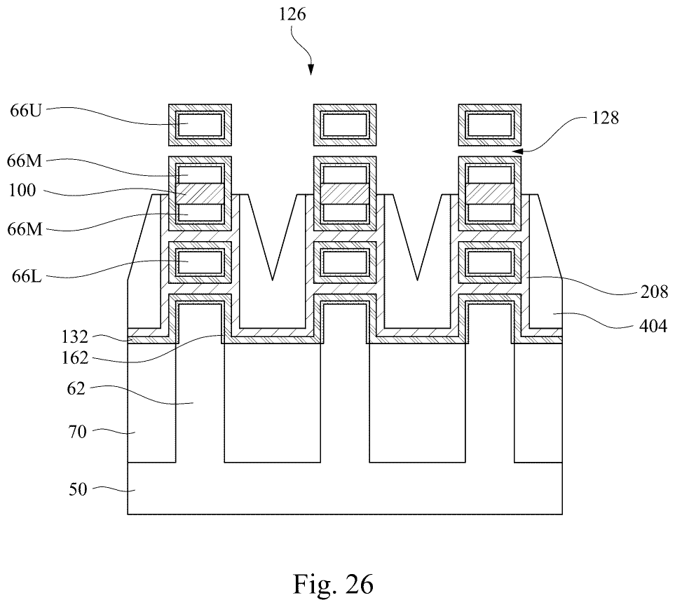

Next, in FIG. 26, the dipole dopant source layer 202 is patterned into patterned dipole dopant source layers 208 by using the dummy fill material 404 as an etch mask. Specifically, in some embodiments, upper portions of the dipole dopant source layer 202 exposed by the dummy fill material 302 and the inhibitors 402 thereon are removed by using, for example, a selective etching process, while leaving lower portions of the dipole dopant source layer 202 protected by the dummy fill material 302. The etching chemical is selected to etch dipole dopant source layer 202, and stops on the gate dielectric layers 132. Accordingly, the portions of dipole dopant source layer 202 on upper semiconductor nanostructures 66U and the upper one of the middle semiconductor nanostructures 66M are removed. The portions of dipole dopant source layer 202 on lower semiconductor nanostructures 66L and the lower one of the middle semiconductor nanostructures 66M are protected by the dummy fill material 302 from being removed. The remaining portions of dipole dopant source layer 202 are collectively referred to as patterned dipole dopant source layers 208. The patterned dipole dopant source layers 208 each have a U-shaped cross-sectional profile with top ends at a level between the top surface level and the bottom surface level of dielectric isolation nanostructures 100.

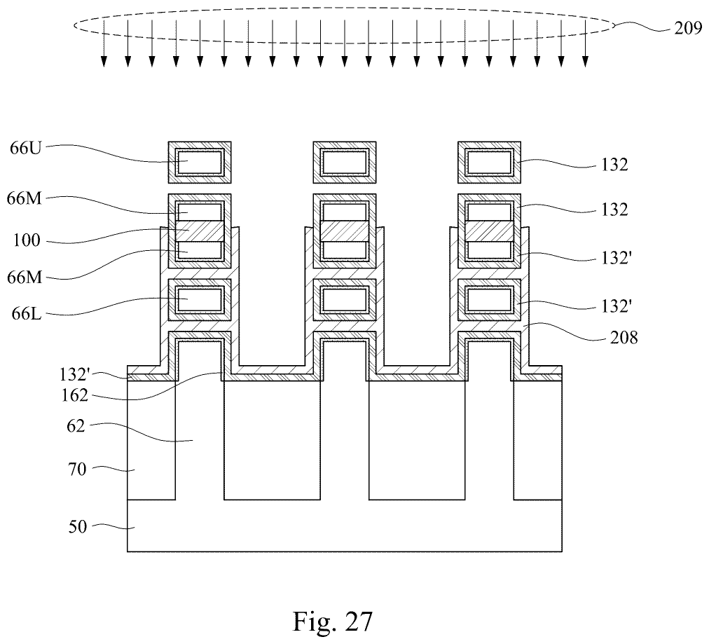

Next, the dummy fill material 404 is removed. The resulting structure is shown in FIG. 27. After the removal of dummy fill material 404, the dipole dopant source layers 208 in the lower FET region are exposed, while in the upper FET region, there is no dipole dopant source layer.

Next, an anneal process 209 is performed to drive the dipole dopants in the patterned dipole dopant source layers 208 into the respective underlying gate dielectric layers 132. The resulting gate dielectric layers 132 with the dipole dopant incorporated are referred to as dipole-doped gate dielectric layers 132′ hereinafter. Upper gate dielectric layers 132 not covered by the dipole dopant source layers 208 may remain un-doped in the anneal process 209. Other details regarding the annealing process 209 are discussed previous with respect to FIG. 12 and thus are not repeated for the sake of brevity.

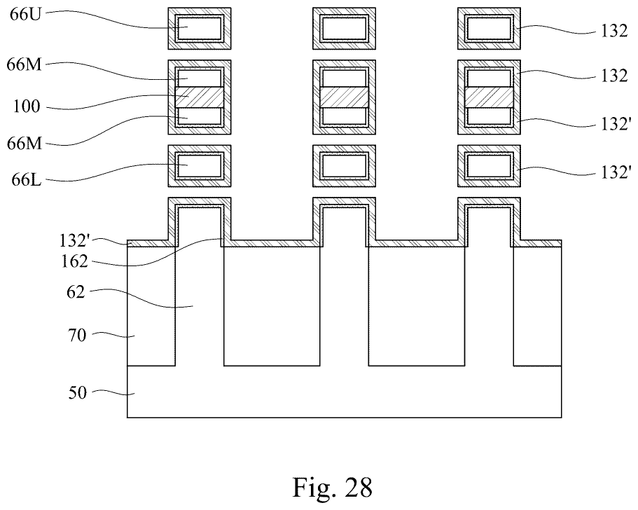

Next, the patterned dipole dopant source layers 208 are removed in a selective etching process that etches the material of the patterned dipole dopant source layers 208 but hardly attacks the material of the gate dielectric layers 132, 132′. Therefore, the gate dielectric layers 132 and 132′ remain intact during the etching process. The resulting structure is shown in FIG. 28, wherein the un-doped upper gate dielectric layers 132 and the dipole-doped lower gate dielectric layers 132′ are exposed.

FIGS. 29A and 29B illustrates the formation of gate electrodes in common processes for an upper FET 10U and a lower FET 10L. The resulting upper FET 10U and lower FET 10L share a common gate electrode 134. The upper portion of the gate electrode 134 that is higher than isolation nanostructures 100 is referred to as upper gate electrode 134U. The lower portion of the gate electrode 134 that is lower than isolation nanostructures 100 is referred to as lower gate electrode 134L. In some embodiments, the gate electrodes 134 each may include one or more work function layers 135 surrounding the dipole-doped gate dielectric layers 132′ and the un-doped gate dielectric layers 132, and a fill metal 136 surrounding the one or more work function layers. Other details regarding the gate electrodes 134 are discussed previously with respect to FIGS. 14A and 14B and thus are not repeated for the sake of brevity.

Based on the above discussions, it can be seen that the present disclosure offers advantages. It is understood, however, that other embodiments may offer additional advantages, and not all advantages are necessarily disclosed herein, and that no particular advantage is required for all embodiments. One advantage is that the CMP over-polishing and loading effect issues can be mitigated by forming the dummy fill material using a bottom-up growth approach.

In some embodiments, a method includes forming a first semiconductor channel region and a second semiconductor channel region above the first semiconductor channel region; forming a first gate dielectric layer and a second gate dielectric layer surrounding the first semiconductor channel region and the second semiconductor channel region, respectively; forming a dipole dopant source layer on the first gate dielectric layer and the second gate dielectric layer; forming a dummy fill material covering a lower portion of the dipole dopant source layer, leaving an upper portion of the dipole dopant source layer uncovered, without subjecting the dummy fill material to a chemical mechanical polish (CMP) process; removing the upper portion of the dipole dopant source layer from the second gate dielectric layer, while retaining the lower portion of the dipole dopant source layer under the dummy fill material; and performing an anneal process to drive a dipole dopant from the lower portion of the dipole dopant source layer into the first gate dielectric layer. In some embodiments, forming the dummy fill material comprises depositing a flowable material over the dipole dopant source layer. In some embodiments, the flowable material is deposited using a plasma-enhanced chemical vapor deposition process. In some embodiments, forming the dummy fill material further comprises curing the flowable material. In some embodiments, the flowable material is cured using an ultraviolet (UV) curing treatment, a thermal curing treatment, or a combination thereof. In some embodiments, wherein forming the dummy fill material comprises performing one or more repetitions of a cycle, wherein the cycle comprises a deposition step and an etching step performed after the deposition step. In some embodiments, after the etching step is completed, the dummy fill material has a concave top surface. In some embodiments, forming the dummy fill material comprises forming inhibitors on the upper portion of the dipole dopant source layer; and depositing the dummy fill material over the dipole dopant source layer. The dummy fill material has a faster deposition rate on the dipole dopant source layer than on the inhibitors. In some embodiments, the inhibitors are formed by performing a plasma treatment to the dipole dopant source layer. In some embodiments, the lower portion of the dipole dopant source layer is free from the inhibitors. In some embodiments, after depositing the dummy fill material over the dipole dopant source layer, the dummy fill material has a V-shaped top surface.

In some embodiments, a method includes forming a first semiconductor nanostructure and a second semiconductor nanostructure above the first semiconductor nanostructure; forming a dielectric isolation nanostructure between the first semiconductor nanostructure and the second semiconductor nanostructure; forming a first gate dielectric layer and a second gate dielectric layer surrounding the first semiconductor nanostructure and the second semiconductor nanostructure, respectively; forming a dipole dopant source layer on the first gate dielectric layer and the second gate dielectric layer; forming a dummy fill material over the dipole dopant source layer, wherein the dummy fill material is formed with a topmost position between a top surface level and a bottom surface level of the dielectric isolation nanostructure, without performing a CMP process on the dummy fill material; with the dummy fill material in place, patterning the dipole dopant source layer; and diffusing a dipole dopant from the patterned dipole dopant source layer into the first gate dielectric layer and not into the second gate dielectric layer. In some embodiments, the method further includes forming a gate electrode on both of the first gate dielectric layer and the second gate dielectric layer. The gate electrode and the first gate dielectric layer form parts of a first transistor, and the gate electrode and the second gate dielectric layer form parts of a second transistor. The first transistor and the second transistor are of different conductivity types. In some embodiments, the method further includes removing the patterned dipole dopant source layer prior to forming the gate electrode, and removing the dummy fill material prior to diffusing the dipole dopant.

In some embodiments, a method includes forming a first semiconductor nanostructure and a second semiconductor nanostructure above the first semiconductor nanostructure; forming a first gate dielectric layer on the first semiconductor nanostructure, and a second gate dielectric layer on the second semiconductor nanostructure; depositing a dipole dopant source layer over the first gate dielectric layer and the second gate dielectric layer; forming a dummy fill material having a topmost position below the second gate dielectric layer, without performing a CMP process on the dummy fill material; etching the dipole dopant source layer by using the dummy fill material as an etch mask; and after etching the dipole dopant source layer, incorporating a dipole dopant of the dipole dopant source layer into the first gate dielectric layer. In some embodiments, forming the dummy fill material comprises depositing a flowable material over the dipole dopant source layer, and curing the flowable material. In some embodiments, forming the dummy fill material comprises performing a deposition step to deposit the dummy fill material over the dipole dopant source layer; performing an etching step to etch back dummy fill material; and repeating the deposition step and the etching step. In some embodiments, forming the dummy fill material comprises performing a plasma treatment to form inhibitors on an upper portion of the dipole dopant source layer; performing a deposition step to deposit the dummy fill material on a lower portion of the dipole dopant source layer; and repeating the plasma treatment and the deposition step.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a first semiconductor channel region and a second semiconductor channel region above the first semiconductor channel region;
forming a first gate dielectric layer and a second gate dielectric layer surrounding the first semiconductor channel region and the second semiconductor channel region, respectively;
forming a dipole dopant source layer on the first gate dielectric layer and the second gate dielectric layer;
forming a dummy fill material covering a lower portion of the dipole dopant source layer, leaving an upper portion of the dipole dopant source layer uncovered, without subjecting the dummy fill material to a chemical mechanical polish (CMP) process;
removing the upper portion of the dipole dopant source layer from the second gate dielectric layer, while retaining the lower portion of the dipole dopant source layer under the dummy fill material; and
performing an anneal process to drive a dipole dopant from the lower portion of the dipole dopant source layer into the first gate dielectric layer.

2. The method of claim 1, wherein forming the dummy fill material comprises depositing a flowable material over the dipole dopant source layer.

3. The method of claim 2, wherein the flowable material is deposited using a plasma-enhanced chemical vapor deposition process.

4. The method of claim 2, wherein forming the dummy fill material further comprises curing the flowable material.

5. The method of claim 4, wherein the flowable material is cured using an ultraviolet (UV) curing treatment, a thermal curing treatment, or a combination thereof.

6. The method of claim 1, wherein forming the dummy fill material comprises performing one or more repetitions of a cycle, wherein the cycle comprises a deposition step and an etching step performed after the deposition step.

7. The method of claim 6, wherein the etching step is performed in-situ with the deposition step.

8. The method of claim 7, wherein after the etching step is completed, the dummy fill material has a concave top surface.

9. The method of claim 1, wherein forming the dummy fill material comprises:
forming inhibitors on the upper portion of the dipole dopant source layer; and
depositing the dummy fill material over the dipole dopant source layer, wherein the dummy fill material has a faster deposition rate on the dipole dopant source layer than on the inhibitors.

10. The method of claim 9, wherein the inhibitors are formed by performing a plasma treatment to the dipole dopant source layer.

11. The method of claim 9, wherein the lower portion of the dipole dopant source layer is free from the inhibitors.

12. The method of claim 9, wherein after depositing the dummy fill material over the dipole dopant source layer, the dummy fill material has a V-shaped top surface.

13. A method, comprising:
forming a first semiconductor nanostructure and a second semiconductor nanostructure above the first semiconductor nanostructure;
forming a dielectric isolation nanostructure between the first semiconductor nanostructure and the second semiconductor nanostructure;
forming a first gate dielectric layer and a second gate dielectric layer surrounding the first semiconductor nanostructure and the second semiconductor nanostructure, respectively;
forming a dipole dopant source layer on the first gate dielectric layer and the second gate dielectric layer;
forming a dummy fill material over the dipole dopant source layer, wherein the dummy fill material is formed with a topmost position between a top surface level and a bottom surface level of the dielectric isolation nanostructure, without performing a CMP process on the dummy fill material;
with the dummy fill material in place, patterning the dipole dopant source layer; and
diffusing a dipole dopant from the patterned dipole dopant source layer into the first gate dielectric layer and not into the second gate dielectric layer.

14. The method of claim 13, further comprising:
forming a gate electrode on both of the first gate dielectric layer and the second gate dielectric layer, wherein the gate electrode and the first gate dielectric layer form parts of a first transistor, and the gate electrode and the second gate dielectric layer form parts of a second transistor, wherein the first transistor and the second transistor are of different conductivity types.

15. The method of claim 14, further comprising:
removing the patterned dipole dopant source layer prior to forming the gate electrode.

16. The method of claim 13, further comprising:
removing the dummy fill material prior to diffusing the dipole dopant.

17. A method, comprising:
forming a first semiconductor nanostructure and a second semiconductor nanostructure above the first semiconductor nanostructure;
forming a first gate dielectric layer on the first semiconductor nanostructure, and a second gate dielectric layer on the second semiconductor nanostructure;
depositing a dipole dopant source layer over the first gate dielectric layer and the second gate dielectric layer;
forming a dummy fill material having a topmost position below the second gate dielectric layer, without performing a CMP process on the dummy fill material;
etching the dipole dopant source layer by using the dummy fill material as an etch mask; and
after etching the dipole dopant source layer, incorporating a dipole dopant of the dipole dopant source layer into the first gate dielectric layer.

18. The method of claim 17, wherein forming the dummy fill material comprises:
depositing a flowable material over the dipole dopant source layer; and
curing the flowable material.

19. The method of claim 17, wherein forming the dummy fill material comprises:
performing a deposition step to deposit the dummy fill material over the dipole dopant source layer;
performing an etching step to etch back dummy fill material; and
repeating the deposition step and the etching step.

20. The method of claim 17, wherein forming the dummy fill material comprises:
performing a plasma treatment to form inhibitors on an upper portion of the dipole dopant source layer;
performing a deposition step to deposit the dummy fill material on a lower portion of the dipole dopant source layer; and
repeating the plasma treatment and the deposition step.
